(19) United States
(12) Patent Application Publication
(10) Pub. No.: US 2026/0064921 A1
(43) Pub. Date: Mar. 5, 2026

(54) METHODS AND SYSTEMS FOR PREDICTING CATALYST CHEMISTRIES

(71) Applicant: Good Chemistry Inc., Tarrytown, NY (US)

(72) Inventors: Kevin Ryczko, Gatineau (CA); Amit Kadan, Vancouver (CA); Benjamin Joseph Shields, Candler, NC (US); Andrew Wildman, Seattle, WA (US); Takeshi Yamazaki, Vancouver (CA)

(21) Appl. No.: 19/316,973

(22) Filed: Sep. 2, 2025

Related U.S. Application Data
(60) Provisional application No. 63/690,460, filed on Sep. 4, 2024.

(51) Int. Cl. G06F 30/27; G06N 3/08

(52) U.S. Cl. CPC G06F 30/27; G06N 3/08

(57) ABSTRACT

In some aspects, the present disclosure provides a method of generating a catalyst for a reaction. In some cases, the method comprises obtaining a reaction template of the reaction. In some cases, the reaction template comprises a reactant. In some cases, the method comprises processing the reaction template to generate a chemical structure of the catalyst based on a differentiable scoring function.

### CROSS-REFERENCE TO RELATED APPLICATION

This application claims priority to U.S. Provisional Patent Application No. 63/690,460, filed Sep. 4, 2024, the entire contents of which are incorporated herein by reference.

### BACKGROUND

Chemical reactions are essential processes in creating molecules and materials. Catalysts are an important component of many such chemical reactions. Therefore, prediction of catalysts for chemical reactions has significant value in various fields, including, synthesizing new molecules and materials for pharmaceutical, advanced material, and energy industries. Computational chemistry is an established tool for predicting a chemical reaction path.

Researchers may predict the outcome of chemical reactions in the presence of catalysts, using computational chemistry methods. Such methods usually involve accounting for electronic degrees of freedom, as reactions generally involve changes in the electronic structure of the molecules and catalysts that are involved. Such methods may involve determining the structure of the transition state of the reaction, in the presence of the catalyst, which can provide an understanding of the likelihood of the reaction occurring in relation to steric and energetic factors.

### SUMMARY

Computational chemistry has become an established tool for the molecular and material discovery process in many areas of industry. Computational chemistry can provide accurate prediction of chemical phenomena and examination of molecular properties that may be inaccessible solely from the experiment and/or requires significant labor. In an example application, computer-aided materials discovery has the potential to be a faster and less expensive approach compared to a laboratory-based materials discovery process.

Computational catalyst design paradigms can involve designing catalyst structures that are configured to react with a given molecule. The design process can involve finding a solution to an inverse design problem, where the desired properties (e.g., reactivity, synthesizability, energy of binding, etc.) are known, but the design of a catalyst with the desired properties is non-trivial. One step in this process can involve sampling of a chemical space, and the other step can be scoring (or evaluating) sampled catalyst's ability to be reactive and to be synthesizable.

There are several challenges in such a design process. First, the explorable chemical space is extremely large, such that an exhaustive search is not practical. Rather, there is a need for a method for efficiently searching the chemical space. Second, existing models may be limited in designing catalysts that satisfy multiple desired physicochemical properties. Third, obtaining information about the transition state of the catalyst in a reaction is computationally complex and expensive. In an aspect, the present disclosure provides, a method that combines generative modeling (e.g., a diffusion model) with multi-objective optimization. In some cases, the latent variables of a generative model are guided to generate one or more ligands of a catalyst while optimizing for a plurality of target properties. In some cases, the plurality of target properties can comprise a binding properties, (e.g., a binding energy or binding affinity to a reactant of interest) and synthetic accessibility.

In an aspect, the present disclosure provides a computational chemistry platform that can generate chemistries that can catalyze a reaction of interest. The method can involve a combination of generative modeling (e.g., a diffusion model) with multi-objective optimization. The method can involve predicting a transition structure of the reaction or energetics associated with the transition structure. In some cases, a predicted chemical reaction path can be generated for the reaction. The predicted chemical reaction path may be used as input to another model, or it may be co-generated with a catalyst structure by model. In some cases, a model of the present disclosure can generate chemical structures for catalysts that can participate in the reaction of interest. In some cases, the model can also be used to generate quantitative measures of the catalyst's feasibility, e.g., an activation energy of the reaction when the catalyst is used for the reaction, a reaction rate given environmental conditions of the reaction, and/or synthetic accessibility of the catalyst.

In some aspects, the present disclosure provides a method of generating a catalyst for a reaction, comprising: (a) obtaining a reaction template of the reaction, wherein the reaction template comprises a reactant; and (b) processing the reaction template, using a neural network, to generate a chemical structure of the catalyst based on a differentiable scoring function, wherein the catalyst is configured to catalyze the reaction. In some cases, the neural network model is configured to predict an activation energy of the reaction, and wherein the activation energy is used to guide the generation of the chemical structure. In some cases, the neural network model is configured to predict an activation energy of the reaction, and wherein the activation energy is used to guide the training of the neural network.

In some cases, the reaction template comprises a structural template for the reaction. In some cases, the reaction template comprises a transition metal complex comprising the catalyst, an alkaline earth metal complex comprising the catalyst, a complex comprising a main group element comprising the catalyst, or a complex comprising a non-metallic element comprising the catalyst. In some cases, the reaction template comprises a binding structure between the reactant and the catalyst. In some cases, the reaction template comprises a transition state of the reaction. In some cases, the reaction template comprises a plurality of reactants. In some cases, the reaction template comprises a product. In some cases, the reaction template comprises a plurality of products. In some cases, the reaction template comprises an environmental condition for the reaction. In some cases, the environmental condition comprises temperature, solvent, additives, pressure, a presence of a gas, agitation, or any combination thereof. In some cases, the reaction template comprises a string-based representation of the reaction. In some cases, the reaction template comprises a graph-based representation of the reaction. In some cases, the reaction template comprises a matrix-based representation of the reaction. In some cases, the matrix-based representation comprises an adjacency matrix, wherein the adjacency matrix comprises indicators for the formation or the destruction of bonds. In some cases, the reaction template indicates a bond in the reactant that is created or broken in the reaction. In some cases, the reaction template indicates a bond in the product that is created or broken in the reaction. In some cases, the reaction template indicates an electron in the reactant or the product that is transferred in the reaction. In some cases, the reaction template comprises a reaction coordinate that represents a reaction path of the reaction.

In some cases, the catalyst comprises a heterogenous catalyst. In some cases, the heterogenous catalyst comprises a transition metal. In some cases, the heterogenous catalyst comprises a transition metal oxide. In some cases, the heterogenous catalyst comprises a catalyst support. In some cases, the catalyst comprises a homogenous catalyst. In some cases, the catalyst comprises a transition metal. In some cases, the catalyst comprises an organometallic. In some cases, the catalyst comprises a ligand. In some cases, the catalyst comprises a plurality of ligands. In some cases, the ligand comprises an organic ligand, an organometallic ligand, a halide, an ether, an alkoxide, an alcohol, a carboxylate, a heterocycle, an amine, an amide, an imine, a nitrile, a phosphine, a metallocene, an n-heterocyclic carbene, an alkyl, an alkene, an alkyne, or any combination thereof. In some cases, the chemical structure of the catalyst is attached to the reaction template.

In some cases, the neural network comprises a generative neural network. In some cases, the generative neural network comprises a diffusion model, an autoencoder, a language model, a graph neural network, of any combination thereof. In some cases, the generative neural network comprises the diffusion model. In some cases, the diffusion model comprises a graph-based diffusion model. In some cases, the processing the reaction template comprises obtaining an input noise and denoising the input noise to generate the chemical structure of the catalyst.

In some cases, gradients of the differentiable scoring function are propagatable to the neural network. In some cases, the differentiable scoring function comprises a second neural network. In some cases, the differentiable scoring function quantifies a feasibility of the catalyst in the reaction. In some cases, the feasibility comprises a binding affinity, an equilibrium constant, synthesizability, an activation energy of the reaction, a binding energy of the reactant to the catalyst, a molecular property of the catalyst, a molecular property of a reactant, a molecular property of a product, a reaction rate of the reaction, selectivity, solvent accessibility of a reaction site in the catalyst, or any combination thereof. In some cases, the molecular property comprise stability or a redox potential. In some cases, the method further comprises determining a reliability of the feasibility. In some cases, the method further comprises determining that the reliability is insufficient, and further comprising performing an ab initio calculation to determine the feasibility.

In some cases, the neural network is trained using data generated using a physics-based computational chemistry method, experimental data, or any combination thereof. In some cases, the second neural network is trained using data generated using a physics-based computational chemistry method, experimental data, or any combination thereof. In some cases, the physics-based computational chemistry method comprises DFT, QMMM, or FEP. In some cases, the neural network is trained using the differentiable scoring function. In some cases, the second neural network is trained independently from the neural network. In some cases, the second neural network is trained together with the neural network.

In some cases, the neural network is configured to guide the generation of the chemical structure based on gradients of a feasibility. In some cases, the neural network is configured to generate a denoising vector based on the gradients. In some cases, the feasibility is an activation energy. In some cases, the denoising vector is applied to a latent variable. In some cases, the neural network is configured to generate a plurality of denoising vectors based on the gradients, wherein the plurality of denoising vectors are applied to the latent variable in a sequence of denoising steps.

In some aspects, the present disclosure provides a processor comprising a communications interface configured to connect to a computing system over a network, the processor configured to: (a) obtain a reaction template of the reaction, wherein the reaction template comprises a reactant; and (b) process the reaction template, using a neural network, to generate a chemical structure of the catalyst based on a differentiable scoring function, wherein the catalyst is configured to catalyze the reaction. In some cases, the neural network model is configured to predict an activation energy of the reaction, and wherein the activation energy is used to guide the generation of the chemical structure. In some cases, the neural network model is configured to predict an activation energy of the reaction, and wherein the activation energy is used to guide the training of the neural network.

In some cases, the reaction template comprises a structural template for the reaction. In some cases, the reaction template comprises a transition metal complex comprising the catalyst, an alkaline earth metal complex comprising the catalyst, a complex comprising a main group element comprising the catalyst, or a complex comprising a non-metallic element comprising the catalyst. In some cases, the reaction template comprises a binding structure between the reactant and the catalyst. In some cases, the reaction template comprises a transition state of the reaction. In some cases, the reaction template comprises a plurality of reactants. In some cases, the reaction template comprises a product.

In some cases, the reaction template comprises a plurality of products. In some cases, the reaction template comprises an environmental condition for the reaction. In some cases, the environmental condition comprises temperature, additives, solvent, pressure, a presence of a gas, agitation, or any combination thereof. In some cases, the reaction template comprises a string-based representation of the reaction. In some cases, the reaction template comprises a graph-based representation of the reaction. In some cases, the reaction template comprises a matrix-based representation of the reaction. In some cases, the matrix-based representation comprises an adjacency matrix, wherein the adjacency matrix comprises indicators for the formation or the destruction of bonds. In some cases, the reaction template indicates a bond in the reactant that is created or broken in the reaction. In some cases, the reaction template indicates a bond in the product that is created or broken in the reaction. In some cases, the reaction template indicates an electron in the reactant or the product that is transferred in the reaction. In some cases, the reaction template comprises a reaction coordinate that represents a reaction path of the reaction.

In some cases, the catalyst comprises a heterogenous catalyst. In some cases, the heterogenous catalyst comprises a transition metal. In some cases, the heterogenous catalyst comprises a transition metal oxide. In some cases, the heterogenous catalyst comprises a catalyst support. In some cases, the catalyst comprises a homogenous catalyst. In some cases, the catalyst comprises a transition metal. In some cases, the catalyst comprises an organometallic. In some cases, the catalyst comprises a ligand. In some cases, the catalyst comprises a plurality of ligands. In some cases, the ligand comprises an organic ligand, an organometallic ligand, a halide, an ether, an alkoxide, an alcohol, a carboxylate, a heterocycle, an amine, an amide, an imine, a nitrile, a phosphine, a metallocene, an n-heterocyclic carbene, an alkyl, an alkene, an alkyne, or any combination thereof. In some cases, the chemical structure of the catalyst is attached to the reaction template.

In some cases, the neural network comprises a generative neural network. In some cases, the generative neural network comprises a diffusion model, an autoencoder, a language model, a graph neural network, of any combination thereof. In some cases, the generative neural network comprises the diffusion model. In some cases, the diffusion model comprises a graph-based diffusion model. In some cases, the processing the reaction template comprises obtaining an input noise and denoising the input noise to generate the chemical structure of the catalyst.

In some cases, gradients of the differentiable scoring function is propagatable to the neural network. In some cases, the differentiable scoring function comprises a second neural network. In some cases, the differentiable scoring function quantifies a feasibility of the catalyst in the reaction. In some cases, the feasibility comprises a binding affinity, an equilibrium constant, synthesizability, an activation energy of the reaction, a binding energy of the reactant to the catalyst, molecular properties of catalyst, reactants, or product, such as stability or redox potential, a reaction rate of the reaction, solvent accessibility of a reaction site in the catalyst, or any combination thereof. In some cases, the neural network is trained using data generated using a physics-based computational chemistry method, experimental data, or any combination thereof. In some cases, the second neural network is trained using data generated using a physics-based computational chemistry method, experimental data, or any combination thereof. In some cases, the physics-based computational chemistry method comprises DFT, QMMM, or FEP. In some cases, the neural network is trained using the differentiable scoring function. In some cases, the second neural network is trained independently from the neural network. In some cases, the second neural network is trained together with the neural network.

In some cases, the neural network is configured to guide the generation of the chemical structure based on gradients of a feasibility. In some cases, the neural network is configured to generate a denoising vector based on the gradients. In some cases, the feasibility is an activation energy. In some cases, the denoising vector is applied to a latent variable. In some cases, the neural network is configured to generate a plurality of denoising vectors based on the gradients, wherein the plurality of denoising vectors are applied to the latent variable in a sequence of denoising steps.

A computer program product comprising a computer-readable medium having computer-executable code encoded therein, the computer-executable code adapted to be executed to implement any one of the systems or methods disclosed herein.

A non-transitory computer-readable storage media encoded with a computer program including instructions executable by one or more processors to implement any one of the systems or methods disclosed herein. A computer-implemented system comprising: a digital processing device comprising: at least one processor, an operating system configured to perform executable instructions, a memory, and a computer program including instructions executable by the digital processing device to perform any one of the systems or methods disclosed herein.

In some aspects, the present disclosure provides methods and systems for studying chemical reaction paths. There are many approaches to determining intermediate molecular geometries and follow the trajectory of molecules in a chemical reaction. However, such calculations may be computationally expensive and/or inaccurate. Accuracy may be particularly useful around the transition state. Density functional theory (DFT) is an example method, but in some cases, DFT fails and a more accurate level of theory such as coupled cluster may be implemented. However, running high accuracy computations such as coupled cluster may be computationally expensive. While classical force field models can describe bond forming and breaking at the level of a classical force field, such as ReaxFF, but their applicability may be limited by the force field parameters. In some aspects, the present disclosure provides a computational chemistry platform that can predict a chemical reaction path accurately and efficiently by flexibly switching the energy and force solver between quantum chemistry or other chemical potential methods, such as DFT, CCSD(T), iFCI, QM/MM, DMET, ONIOM, and force field based potentials, and a machine learning (ML) model trained to the level of the quantum chemistry or chemical potential method, depending on the reliability of the inference that the ML model provides. If the platform indicates that the ML inference for a geometry along the reaction path is reliable, the platform continues using the ML model for that geometry. But when the platform indicates that the ML inference is less reliable, the platform may switch to a quantum chemistry method to solve the target geometry. In this way, the present disclosure increases both accuracy and efficiency.

In another example of increasing accuracy and efficiency, the results obtained from the quantum chemistry calculations may be stored in the platform's database as the training dataset to improve the ML model. In this way, the platform may reduce the number of times the quantum chemistry methods are used to solve the target geometry, and the platform may continuously improve the ML model to predict chemical reactions faster and more accurately. In an aspect, the present disclosure provides a computer-implemented method for determining a reaction path. The method may comprise: (a) providing an indication of a reactant and at least one of a product or a driving coordinate; (b) providing a set of coordinates, wherein said set of coordinates is on an energy surface connecting said reactant and said at least one of said product or said driving coordinate; (c) evaluating an energy or a force at a coordinate of said set of coordinates using a trained model; (d) determining that a reliability metric at said coordinate is less than a threshold reliability value; (e) evaluating an energy or a force at said coordinate based at least in part on a quantum chemistry calculation corresponding to a training data set of said trained model; and (f) outputting a set of energies or forces at said set of coordinates on said energy surface based at least in part on said energy or force in (e) and said energy or said force in (c).

In some cases, energy surface is a potential energy surface. In some cases, said energy surface is a free energy surface. In some cases, said set of coordinates are a conformation coordinate. In some cases, said set of coordinates are cartesian coordinates. In some cases, said cartesian coordinates comprise a direction of movement. In some cases, (e) comprises evaluating an ab initio energy or an ab initio force at said coordinate.

In some cases, the method further comprises, until a completion criterion is met: (i) if said reliability metric is less than said threshold reliability value: evaluating said energy or said force at said coordinate in (c), selecting another coordinate on said energy surface, using said trained model to evaluate said energy or said force at said another coordinate, and determining a reliability metric for said energy or said force at said another coordinate; and (ii) if said reliability metric is greater than said threshold reliability value: selecting another coordinate on said energy surface, using said trained model to evaluate said energy at said another coordinate, and determining a reliability metric for said energy or said force at said another coordinate. In some cases, at (i), the method further comprises saving said energy or force for retraining and retraining said trained model based on said energy or said force in (i). In some cases, selecting said another coordinate on said energy surface comprises a method selected from the group consisting of ab initio molecular dynamics, nudged elastic band, growing string method, a variational reaction path optimization method, and intrinsic reaction coordinate.

In some cases, the method further comprises at (e) saving said energy or said force for retraining and retraining said trained model based on said energy or said force in (c). In some cases, the method further comprises using said trained model to evaluate a first energy or a first force at an initial coordinate. In some cases, the method further comprises determining a reliability metric for said first energy or said first force at said initial coordinate. In some cases, (f) further comprises outputting a transition state or a reaction path on said energy surface. In some cases, said reaction path is a minimum energy path.

In some cases, providing a set of coordinates in (b) comprises a method selected from the group consisting of ab initio molecular dynamics, nudged elastic band, growing string method, a variational reaction path optimization method, and intrinsic reaction coordinate. In some cases, said trained model comprises a machine learning algorithm. In some cases, said machine learning algorithm comprises a neural network. In some cases, said machine learning algorithm comprises an ensemble learning method. In some cases, (d) comprises combining results from one or more sub-models to create a metamodel, calculating an energy for each of said one or more sub-models, and calculating a standard deviation of energy for said one or more sub-models, wherein said standard deviation comprises a part of said reliability metric. In some cases, said metamodel comprises an ANI deep learning potential. In some cases, said one or more sub-models comprises one or more of PAINN deep learning potentials, DimeNet++deep learning potentials, or PauliNet.

In some cases, (e) comprises evaluating an ab initio energy or an ab initio force at said coordinate, and wherein said ab initio energy or said ab initio force is calculated by a Hartree-Fock method, a coupled cluster method, full configuration interaction, incremental full configuration interaction, density functional theory, Moller-Plesset perturbation theory, mixed quantum mechanical and molecular mechanical methods, density matrix embedding theory, or ONIOM models.

In another aspect, the present disclosure provides a computer-implemented method for determining a reaction path. The method may comprise: (a) providing an indication of a reactant and at least one of a product or a driving coordinate; (b) providing a set of coordinates, wherein said set of coordinates is on an energy surface connecting said reactant and said at least one of said product or said driving coordinate; (c) evaluating an energy or a force at a coordinate of said set of coordinates using a trained model; (d) evaluating an energy or a force at said coordinate based at least in part on a quantum chemistry calculation corresponding to a training data set of said trained model; and (e) retraining said trained model based on said energy or said force in (d).

In some cases, said energy surface is a potential energy surface. In some cases, said energy surface is a free energy surface. In some cases, said set of coordinates are a conformation coordinate. In some cases, said set of coordinates are cartesian coordinates. In some cases, said cartesian coordinates comprise a direction of movement. In some cases, (d) comprises evaluating an ab initio energy or an ab initio force at said coordinate. In some cases, the method further comprises: outputting a set of energies or forces at said set of coordinates on said energy surface based at least in part on said energy or force in (d).

In some cases, said trained model comprises a machine learning algorithm. In some cases, said machine learning algorithm comprises a neural network. In some cases, said machine learning algorithm comprises an ensemble learning method. In some cases, (c) comprises: combining results from one or more sub-models to create a metamodel, calculating an energy for each of said one or more sub-models, and calculating a standard deviation of energy for said one or more sub-models, wherein said standard deviation comprises a reliability metric. In some cases, said metamodel comprises an ANI deep learning potential. In some cases, said one or more sub-models comprises one or more of PAINN deep learning potentials, DimeNet++deep learning potentials, or PauliNet. In some cases, (d) comprises evaluating an ab initio energy or an ab initio force at said coordinate, and wherein said ab initio energy or said ab initio force is calculated by a Hartree-Fock method, a coupled cluster method, full configuration interaction, incremental full configuration interaction, density functional theory, Moller-Plesset perturbation theory, mixed quantum mechanical and molecular mechanical methods, density matrix embedding theory, or ONIOM models.

In some cases, the method further comprises: until a completion criterion is met: (i) if a reliability metric is less than said threshold reliability value: evaluating said energy or said force at said coordinate in (c), selecting another coordinate on said energy surface, using said trained model to evaluate said energy or said force at said another coordinate, and determining a reliability metric for said energy or said force at said another coordinate; and (ii) if a reliability metric is greater than said threshold reliability value: selecting another coordinate on said energy surface, using said trained model to evaluate said energy at said another coordinate, and determining a reliability metric for said energy or said force at said another coordinate. In some cases, the method further comprises at (i) saving said energy or force for retraining and retraining said trained model based on said energy or said force in (i).

In some cases, the method further comprises using said trained model to evaluate a first energy or a first force at an initial coordinate. In some cases, the method further comprises determining a reliability metric for said first energy or said first force at said initial coordinate. In some cases, said providing a set of coordinates in (b) comprises a method selected from the group consisting of: ab initio molecular dynamics, nudged elastic band, growing string method, a variational reaction path optimization method, and intrinsic reaction coordinate. In some cases, said selecting said another coordinate on said energy surface comprises a method selected from the group consisting of: ab initio molecular dynamics, nudged elastic band, growing string method, a variational reaction path optimization method, and intrinsic reaction coordinate.

In another aspect, the present disclosure provides a computer-implemented method for determining a reaction path. The method may comprise: (a) providing an indication of a reactant and at least one of a product or a driving coordinate; (b) providing a set of coordinates, wherein said set of coordinates is on an energy surface connecting said reactant and said at least one of said product or said driving coordinate; (c) providing a threshold reliability value for an energy or a force at a coordinate of said set of coordinates and, until a completion criterion is met: (i) if a reliability metric is less than said threshold reliability value: evaluating an energy or a force at said coordinate, selecting another coordinate on said energy surface, using a trained model to evaluate said energy or said force at said another coordinate, and determining said reliability metric for said energy or said force at said another coordinate; and (ii) if said reliability metric is greater than said threshold reliability value: selecting another coordinate on said potential energy surface, using said trained model to evaluate said energy at said another coordinate, and determining a reliability metric for said energy or said force at said another coordinate; and (d) outputting a set of energies or forces at said set of coordinates on said energy surface.

In some cases, said energy surface is a potential energy surface. In some cases, said energy surface is a free energy surface. In some cases, said set of coordinates are a conformation coordinate. In some cases, said set of coordinates are cartesian coordinates. In some cases, said cartesian coordinates comprise a direction of movement. In some cases, (c) comprises evaluating an ab initio energy or an ab initio force at said coordinate.

In some cases, the method further comprises retraining said trained model based on at least one energy or at least one force within set said set of coordinates. In some cases, the method further comprises said trained model to evaluate a first energy or a first force at an initial coordinate. In some cases, the method further comprises determining a reliability metric for said first energy or said first force at said initial coordinate. In some cases, (f) further comprises outputting a transition state or a reaction path on said energy surface. In some cases, said reaction path is a minimum energy path. In some cases, said providing a set of coordinates in (b) comprises a method selected from the group consisting of: ab initio molecular dynamics, nudged elastic band, growing string method, a variational reaction path optimization method, and intrinsic reaction coordinate. In some cases, said selecting said another coordinate on said energy surface comprises a method selected from the group consisting of: ab initio molecular dynamics, nudged elastic band, growing string method, a variational reaction path optimization method, and intrinsic reaction coordinate.

In some cases, said trained model comprises a machine learning algorithm. In some cases, said machine learning algorithm comprises a neural network. In some cases, said machine learning algorithm comprises an ensemble learning method. In some cases, (d) comprises: combining results from one or more sub-models to create a metamodel, calculating an energy for each of said one or more sub-models, and calculating a standard deviation of energy for said one or more sub-models, wherein said standard deviation comprises a part of said reliability metric. In some cases, said metamodel comprises an ANI deep learning potential. In some cases, said one or more sub-models comprises one or more of PAINN deep learning potentials, DimeNet++deep learning potentials, or PauliNet. In some cases, (c) comprises evaluating an ab initio energy or an ab initio force at said coordinate, and wherein said ab initio energy or said ab initio force is calculated by a Hartree-Fock method, a coupled cluster method, full configuration interaction, incremental full configuration interaction, density functional theory, Moller-Plesset perturbation theory, mixed quantum mechanical and molecular mechanical methods, density matrix embedding theory, or ONIOM models.

In another aspect, the present disclosure provides a computer-implemented method for determining a reaction path. The method may comprise: (a) providing an indication of a reactant and at least one of a product or a driving coordinate; (b) providing a set of conformational coordinates, wherein said set of conformational coordinates is on a potential energy surface connecting said reactant and said at least one of said product or said driving coordinate; (c) using a trained model to evaluate an energy or a force at a conformational coordinate of said set of conformation coordinates; (d) determining that a reliability metric at said conformational coordinate is less than a threshold reliability value; (c) evaluating an ab initio energy or an ab initio force at said conformational coordinate; and (f) outputting a set of energies or forces at said set of conformational coordinates on said potential energy surface based at least in part on said ab initio energy or ab initio force and said energy or said force in (c).

In some cases, the method further comprises: until a completion criterion is met: (i) if said reliability metric is less than said threshold reliability value: evaluating said ab initio energy or said ab initio force at said conformational coordinate, selecting another conformation coordinate on said potential energy surface, using said trained model to evaluate said energy or said force at said another conformational coordinate, and determining a reliability metric for said energy or said force at said another conformational coordinate; and (ii) if said reliability metric is greater than said threshold reliability value: selecting another conformational coordinate on said potential energy surface, using said trained model to evaluate said energy at said another conformational coordinate, and determining a reliability metric for said energy or said force at said another conformational coordinate. In some cases, the method further comprises: at (c) saving said ab initio energy or said ab initio force for retraining and retraining said trained model based on said ab initio energy or said ab initio force. In some cases, the method further comprises: at (i) saving said ab initio energy or said ab initio force for retraining and retraining said trained model based on said ab initio energy or said ab initio force.

In some cases, the method further comprises: using said trained model to evaluate a first energy or a first force at an initial conformational coordinate. In some cases, the method further comprises: determining a reliability metric for said first energy or said first force at said initial conformational coordinate. In some cases, (f) further comprises outputting a transition state or a reaction path on said potential energy surface. In some cases, said reaction path is a minimum energy path. In some cases, said providing a set of conformational coordinates in (b) comprises a method selected from the group consisting of: ab initio molecular dynamics, nudged clastic band, growing string method, a variational reaction path optimization method, and intrinsic reaction coordinate. In some cases, said selecting said another conformational coordinate on said potential energy surface comprises a method selected from the group consisting of: ab initio molecular dynamics, nudged elastic band, growing string method, a variational reaction path optimization method, and intrinsic reaction coordinate.

In some cases, said trained model comprises a machine learning algorithm. In some cases, said machine learning algorithm comprises a neural network. In some cases, said machine learning algorithm comprises an ensemble learning method. In some cases, (d) comprises: combining results from one or more sub-models to create a metamodel, calculating an energy for each of said one or more sub-models, and calculating a standard deviation of energy for said one or more sub-models, wherein said standard deviation comprises a part of said reliability metric. In some cases, said metamodel comprises an ANI deep learning potential. In some cases, said one or more sub-models comprises one or more of PAINN deep learning potentials, DimeNet++deep learning potentials, or PauliNet. In some cases, said ab initio energy or said ab initio force is calculated by a Hartree-Fock method, a coupled cluster method, full configuration interaction, incremental full configuration interaction, density functional theory, Moller-Plesset perturbation theory, mixed quantum mechanical and molecular mechanical methods, density matrix embedding theory, or ONIOM models.

In another aspect, the present application provides a computer-implemented method for determining a reaction path. The method may comprise: (a) providing an indication of a reactant and at least one of a product or a driving coordinate; (b) providing a set of conformational coordinates, wherein said set of conformational coordinates is on a potential energy surface connecting said reactant and said at least one of said product or said driving coordinate; (c) using a trained model to evaluate an energy or a force at a conformational coordinate of said set of conformational coordinates; (d) evaluating an ab initio energy or an ab initio force at said conformational coordinate; and (c) retraining said trained model based on said ab initio energy or said ab initio force.

In some cases, the method further comprises: outputting a set of energies or forces at said set of conformational coordinates on said potential energy surface based at least in part on said ab initio energy or ab initio force. In some cases, said trained model comprises a machine learning algorithm. In some cases, said machine learning algorithm comprises a neural network. In some cases, said machine learning algorithm comprises an ensemble learning method. In some cases, (c) comprises: combining results from one or more sub-models to create a metamodel, calculating an energy for each of said one or more sub-models, and calculating a standard deviation of energy for said one or more sub-models, wherein said standard deviation comprises said reliability metric. In some cases, said metamodel comprises an ANI deep learning potential. In some cases, said one or more sub-models comprises one or more of PAINN deep learning potentials, DimeNet++deep learning potentials, or PauliNet.

In another aspect, the present disclosure provides, a computer-implemented method for determining a reaction path. The method may comprise: (a) providing an indication of a reactant and at least one of a product or a driving coordinate; (b) providing a set of conformational coordinates, wherein said set of conformational coordinates is on a potential energy surface connecting said reactant and said at least one of said product or said driving coordinate; (c) providing a threshold reliability value for an energy or a force at a conformational coordinate of said set of conformational coordinates and, until a completion criterion is met: (i) if a reliability metric is less than said threshold reliability value: evaluating an ab initio energy or an ab initio force at said conformational coordinate, selecting another conformation coordinate on said potential energy surface, using a trained model to evaluate said energy or said force at said another conformational coordinate, and determining said reliability metric for said energy or said force at said another conformational coordinate; and (ii) if said reliability metric is greater than said threshold reliability value: selecting another conformational coordinate on said potential energy surface, using said trained model to evaluate said energy at said another conformational coordinate, and determining a reliability metric for said energy or said force at said another conformational coordinate; and (d) outputting a set of energies or forces at said set of conformational coordinates on said potential energy surface.

In some cases, the method further comprises retraining said trained model based on at least one ab initio energy or at least one ab initio force within set said set of conformational coordinates.

In another aspect, the present disclosure provides a computer program product comprising a computer-readable medium having computer-executable code encoded therein, the computer-executable code adapted to be executed to implement a method or a system disclosed herein.

In another aspect, the present disclosure provides a non-transitory computer-readable storage media encoded with a computer program including instructions executable by one or more processors to implement a method or a system disclosed herein.

In another aspect, the present disclosure provides a computer-implemented system comprising: a digital processing device comprising: at least one processor, an operating system configured to perform executable instructions, a memory, and a computer program including instructions executable by the digital processing device to implement a method or a system disclosed herein.

Another aspect of the present disclosure provides a system comprising one or more computer processors and computer memory coupled thereto. The computer memory comprises machine executable code that, upon execution by the one or more computer processors, implements any of the methods above or elsewhere herein.

In some cases, the system further comprises a quantum computer, wherein the quantum computer is configured to perform an operation of any of the methods above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The patent or application file contains at least one drawing executed in color. Copies of this patent or patent application publication with color drawing(s) will be provided by the Office upon request and payment of the necessary fec. The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 is a flowchart of an example of a method for determining a reaction path, in accordance with some embodiments.

FIG. 2 is a flowchart of another example of a method for determining a reaction path when the reliability is less than a threshold value, in accordance with some embodiments.

FIG. 3 is a flowchart of an example of a method for determining a reaction path and using data from a quantum chemistry calculation to update a trained model, in accordance with some embodiments.

FIG. 4 is a flowchart an example of a method for determining a reaction path showing branching pathways based on a reliability metric, in accordance with some embodiments.

FIG. 5, there is shown an example schematic diagram of a system for determining a reaction path, in accordance with some embodiments.

FIG. 6 shows a computer system that is programmed or otherwise configured to implement methods provided herein.

FIG. 7 is a diagram of a chemical reaction between s-cis-butadiene and ethene to form cyclohexene.

FIG. 8 is a plot of computational data showing: reaction path energy profiles for DFT (solid), ANI/ANI1x (dashed), and ANI/Transition1x (dotted); GSM node energies (open circles); and intermediate values estimated with a cubic spline interpolation (regression lines).

FIG. 9A is computational data showing molecular structures for the reactants (left), transition state (center), and products (right) predicted by GSM using the ANI/ANI1x model.

FIG. 9B is computational data showing molecular structures for the reactants (left), transition state (center), and products (right) predicted by GSM using the ANI/Transition1x model.

FIG. 9C is computational data showing molecular structures for the reactants (left), transition state (center), and products (right) predicted by GSM using the DFT model.

FIG. 10 shows overlaid transition state structures predicted by GSM using DFT, (filled, 1030) ANI/ANI1x, (open, 1010) and ANI/Transition1x. (textured, 1020), where all structures have been translated to have the same overall center of mass.

FIG. 11 is a flowchart of a method for determining a chemical structure of a catalyst for a chemical reaction.

FIG. 12 is a flowchart of a method for determining a chemical structure of a catalyst for a chemical reaction using reliability metrics.

FIG. 13 is a flowchart of a method for determining a chemical structure of a catalyst for a chemical reaction using an equivariant diffusion model and differentiable scoring functions.

FIG. 14 is a flowchart of a method for determining a chemical structure of a catalyst for a chemical reaction using an equivariant diffusion model and differentiable scoring functions.

FIG. 15 is a flowchart of a method for determining a chemical structure of a catalyst for a chemical reaction using an equivariant diffusion model and differentiable scoring functions.

FIG. 16 is a flowchart of a method for determining a chemical structure of a catalyst for a chemical reaction using an equivariant diffusion model and differentiable scoring functions.

FIG. 17 is a flowchart of training an equivariant diffusion model for determining a chemical structure of a catalyst for a chemical reaction.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

The term “plurality” means “two or more,” unless expressly specified otherwise.

The term “herein” means “in the present application, including anything which may be incorporated by reference,” unless expressly specified otherwise.

The term “e.g.,” and like terms mean “for example,” and thus do not limit the terms or phrases they explain. For example, in a sentence “the computer sends data (e.g., instructions, a data structure) over the Internet,” the term “e.g.,” explains that “instructions” are an example of “data” that the computer may send over the Internet, and also explains that “a data structure” is an example of “data” that the computer may send over the Internet. However, both “instructions” and “a data structure” are merely examples of “data,” and other things besides “instructions” and “a data structure” can be “data.”

Certain inventive embodiments herein contemplate numerical ranges. When ranges are present, the ranges include the range endpoints. Additionally, every sub range and value within the range is present as if explicitly written out.

The term “about” or “approximately” may mean within an acceptable error range for the particular value, which will depend in part on how the value is measured or determined, e.g., the limitations of the measurement system. For example, “about” may mean within 1 or more than 1 standard deviation, per the practice in the art. Alternatively, “about” may mean a range of up to 20%, up to 10%, up to 5%, or up to 1% of a given value. Where particular values are described in the application and claims, unless otherwise stated the term “about” meaning within an acceptable error range for the particular value may be assumed.

In the following detailed description, reference is made to the accompanying figures, which form a part hereof. In the figures, similar symbols typically identify similar components, unless context dictates otherwise. The illustrative embodiments described in the detailed description, figures, and claims are not meant to be limiting. Other embodiments may be used, and other changes may be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

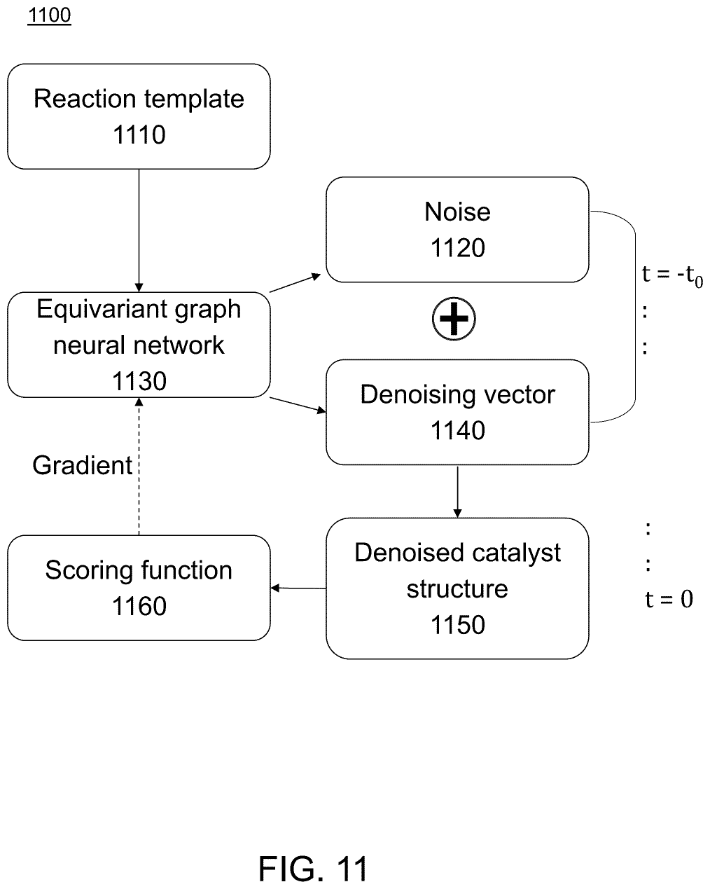

The present disclosure provides a method of generating a catalyst for a reaction. FIG. 11 shows a schematic of an example of the method. The method can comprise obtaining an indication of reaction. The indication of the reaction can be a reaction template 1110 of the reaction. The reaction template can be a computer-readable representation of a chemical reaction. For example, the reaction template can define a reaction by expressing a reactant, a product, a catalyst, or any combination thereof, to catalyze the reaction. The reaction template can be expressed using SMILES arbitrary target specification (SMARTS), or any other suitable format that can define a reactant, a product, a catalyst, or any combination thereof. In some cases, the reaction template can be expressed using a chemical structure of a transition state (e.g., an intermediate structure of a reactant or product that is bound to a catalyst). The catalyst in the reaction template can comprise open-ended or undefined ligands. For example, the catalyst can comprise a transition metal atom bound to a plurality of R-groups.

The method can comprise processing the reaction template. The processing can generate a chemical structure 1150 of the catalyst. The generated chemical structure of the catalyst can comprise define the exact chemical structure of the ligands. For instance, the undefined ligands of the catalyst can become explicitly defined. Rather than providing R-groups, the chemical structure of the catalyst can define the arrangement of atoms and bonds that make up the R-groups.

The processing can be performed using a ML model 1130. The ML model can be one of various of models. The ML model can be a neural network. The neural network can comprise an equivariant diffusion model. The diffusion model can be configured to generate a series of denoising vectors 1140 that can be added to an initial noise vector 1120 to generate a denoised output. The diffusion model can be configured such that its denoised output comprises the chemical structure of the catalyst 1150.

The processing can be performed using a differentiable scoring function 1160. The differentiable scoring function can be used to score the output of the ML model. The differentiable scoring function can be differentiated to propagate its gradients to the ML model. The differentiable scoring function can be used to update the parameters of the ML model. In some cases, the differentiable scoring function can be comprised in a second ML model, wherein the second ML model is operably connected to the ML model for generating the chemical structure. In some cases, the differentiable scoring function can be integrated into the ML model for generating the chemical structure. The differentiable scoring function can comprise an artificial neural networks (e.g., ANI) or a graph neural network (e.g., MACE, equiformerV2, PaiNN, etc.). In some cases, the ML model is trained using the differentiable scoring function. In some cases, the second ML model is trained independently from the ML model. In some cases, the second ML model is trained together with the ML model.

In some cases, the output of the ML model can comprise a geometrical structure of the transition state of the reaction. The transition state can be, e.g., an intermediate structure having the catalyst and the reactant bonded to each other. Predicting the transition state geometry can help the ML model evaluate the activation energy associated with the reaction. Without being bound to a particular theory, transition state theories of reactions show that the activation energy associated with arriving at the transition state from initial reactant(s) is exponentially related to the reaction rate. Thus, when a ML model is configured to generate a geometrical structure of the transition state, the ML model may also learn information that is related to the activation energy of the reactions.

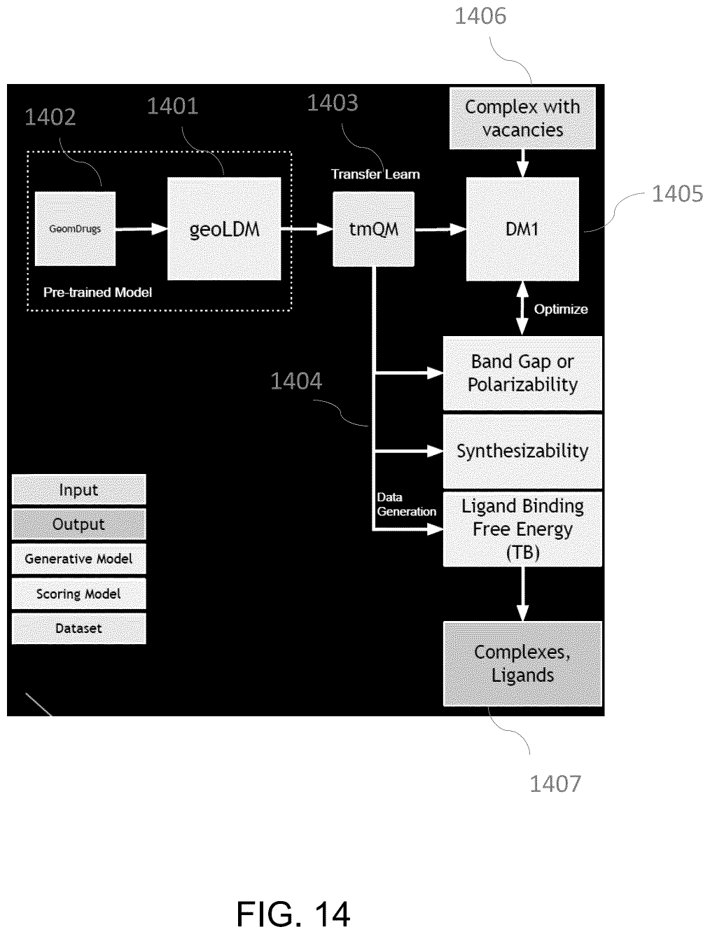

FIG. 14 illustrates a schematic for making and using a model for generating catalysts. In some cases, the ML model can comprise a neural network 1401. The neural network can be a diffusion model. The neural network can be configured with roto-translational equivariant constraints. The neural network can comprise a point-structured latent space, invariant scalars, equivariant tensors, or any combination thereof. The neural network can comprise an encoder. The encoder can be configured to encode features into latent variables. The features can be molecular features. The latent variables can be equivariant latent variables.

The neural network can be configured to generate noise vectors. The noise vectors can be used added as noise to the latent variables. The noise vectors can be added in a series of steps such that the latent variables converge to Gaussians.

During inference, an initial latent variable can be sampled from a normal distribution. The latent variable can be denoised by adding a denoising vector. The denoising vector can be equivariant. The denoising vectors can be added in a series of steps. The resulting denoised latent variable can be decoded back to a molecular structure with a decoder. The molecular structure can be, e.g., a molecular point cloud.

The model can be pretrained with a dataset 1402 having various molecules, conformations, and energy annotations, e.g., GEOM or GEOMDRUGS which can have tens of millions of samples.

The ML model can be trained/fine-tuned on a dataset 1403 specific for catalysts. As datasets regarding catalysts (e.g., transition metal complexes) can be more expensive to obtain, pretraining on a larger dataset geared toward more general chemistries such as GEOM or GEOMDRUGS can allow model to generalize better to unseen molecular structures. This generalization can perform well because catalyst structures (e.g., transition metal complexes) may include ligands which may have similar geometries and energetics as similar ligands/molecules found in a general dataset.

The dataset 1403 can comprises various features such as the geometries, atomic charges (e.g., natural atomic charges), bond orders (e.g., Wiberg bond orders). Other features can also be obtained from electronic structure calculations using available software like ORCA or GAUSSIAN. The tmQM dataset, for example, has 108k transition metal complexes including transition metals across the 3d, 4d, and 5d series combined with more than 30k different ligands, and also including organometallic, bioinorganic, and Werner complexes.

The catalyst dataset 1403 can be augmented with additional annotations/labels. The annotations or labels can provide additional information for the ML model to learn from, or to use during inference, to guide the generation of molecules towards ones that have desired metrics. These annotations and/or labels can be generated by performing computational chemistry calculations or simulations to obtain, for example band gap energies, polarizability, synthesizability, ligand binding free energy, etc.

When training the ML model, the ML model can be coupled to one or more differentiable scoring functions 1404. The differentiable scoring functions can be configured to provide gradients from annotations and/or labels to the ML model such that the ML model learns to associate certain catalysts with desirable properties. Thus, the ML model can learn to generate more desirable catalysts. These catalysts can be more synthesizable, have more favorable ligand binding free energies (e.g., favorable but not too strong so that ligands may be released after a reaction), etc.

In some cases, the one or more differentiable scoring functions can be trained independently and prior to the training of the ML model with the annotations/labels. In some cases, the one or more differentiable scoring functions can also be trained with the ML model at the same time. In some cases, the differentiable scoring function can be used not to train the ML model, and instead, can be used only for inference.

Once trained, the trained ML model 1405 can be used to generate catalyst structures by providing a structure of catalyst with one or more vacancies 1406 (e.g., open functional groups where specific ligand structures can be generated). The structure can be encoded into a latent space using an encoder. The ML model can generate denoising vectors that update the latent variable. The denoising vectors can be generated with feedback from the one or more differentiable scoring functions such that the denoising vectors steer the generation towards catalysts that have more desirable characteristics, e.g., better synthesizability, better ligand binding free energies, etc. Desirable characteristics can also include macroscopic properties of the catalyst in reactors, such as flow distribution, heat and mass transfer, etc. The denoising vectors can be deterministic, such that the gradients of the scoring functions can flow all the way back to the first step of the denoising process. The denoised latent variable can be decoded to generate an atomic/molecular structure of the catalyst 1407.

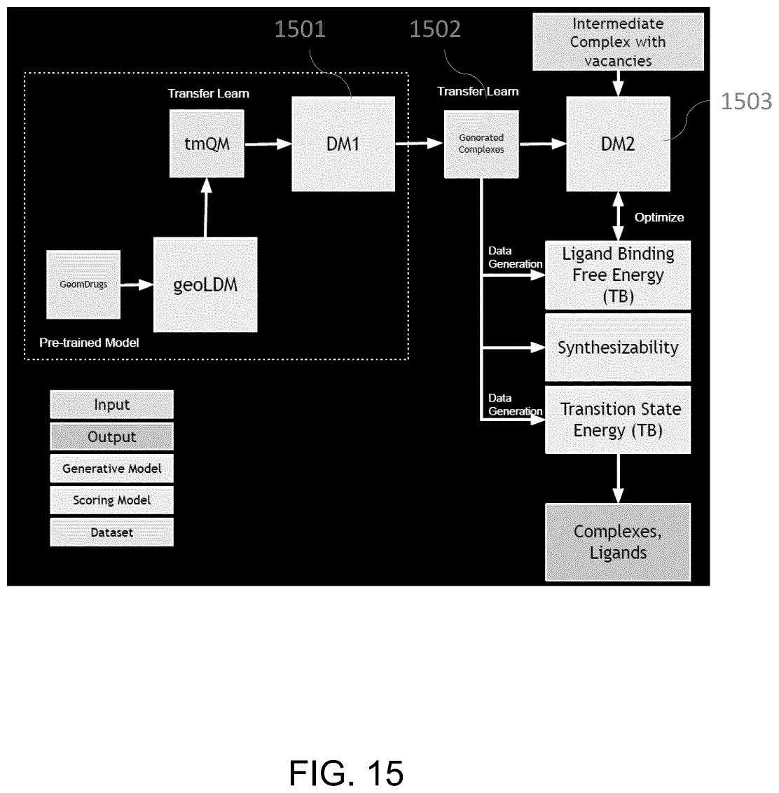

The trained ML model can be used to generate a large dataset of catalyst structures. FIG. 15 illustrates a schematic for using a model to generate a dataset to train a neural model. The trained ML model 1501 can be used to generate a dataset comprising a plurality of catalyst structures 1502. While these catalyst structures are generated by a ML model that is configured to steer generation towards structures that meet certain objectives defined by the differentiable scoring functions, there is an opportunity to further refine the distribution of generated structures by allowing the ML model to learn on information about the transition state structures or transition state energies of those structures.

Without being bound to a particular theory, the transition theory of chemical reactions (e.g., as expressed by the Arrhenius equation or the Eyring equation) indicates that there is an exponential relationship between the activation energy of a reaction and the reaction rate. Thus, the transition state structure and the activation energy of the reaction (which can be quantified as the difference in energy between the transition state versus the reactants), can provide salient information regarding viable catalyst structure generation.

In some cases, a training dataset can be generated comprising the dataset comprising the plurality of catalyst structures, and features associated with the plurality of catalyst structures. The features can be, e.g., activation energy. The training dataset can be used to train/fine-tune the ML model to such that the ML model learns a new distribution of catalyst structures that are more likely to be successful ex silico.

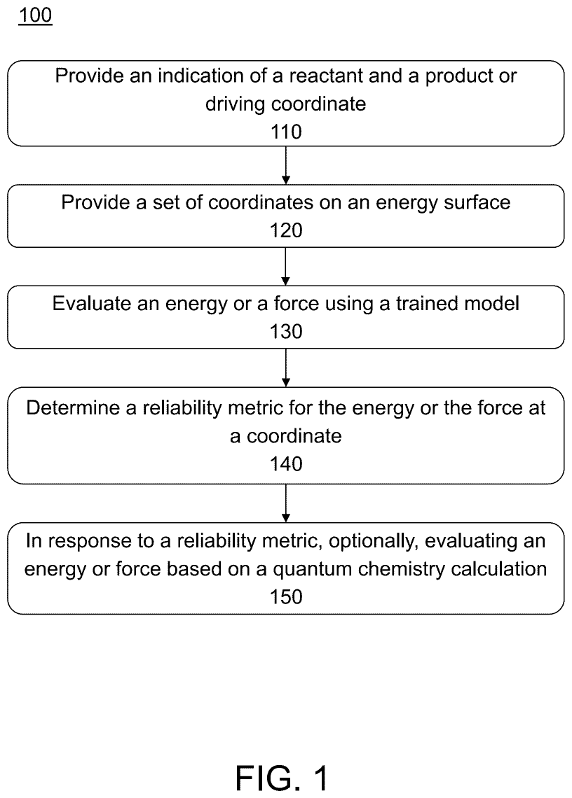

The features can be calculated using various methods. In some cases, the features can comprise transition states of catalyst structures. The transition states can be obtained using a method or system of the present disclosure (e.g., as illustrated in FIGS. 1-5 or Example 1). Other methods can be used, e.g., nudged-elastic band, adaptive bias sampling, etc.

In some cases, the activation energy can be quantified by taking the difference in the potential energy of the transition state and the summed potential energy of the reactant(s) and the catalyst. In some cases, the potential energy can be calculated using Tight Binding (TB), density function theory (DFT), or another electronic structure calculation.

In some cases, the activation energy of the reaction can be quantified by taking the difference in the free energy of the transition state and the summed free energy of the reactant(s) and the catalyst. In some cases, the free energy can be calculated using TB, DFT, or another electronic structure calculation. In some cases, the electronic structure calculation can be used to provide the Hessian, which can be used to calculate the free energy contributions that come from vibrational modes based on a harmonic assumption of the vibrational degrees of freedom. In some cases, the features comprise free energy contributions from vibrational modes. In some cases, the free energy contributions from vibrational modes are based on a harmonic assumption of the vibrational degrees of freedom. In some cases, the electronic structure calculation can be performed using implicit or explicit solvent. Explicit solvent may be more accurate if the catalyst is expected to have specific interactions with the solvent that influences that molecular structure of the catalyst in the transition state and/or before binding with a reactant.

Another way to compute the free energy is to perform Car-Parrinello molecular dynamics. The electronic degrees of freedom for the entire or a subset of the system can be accounted for using an electronic structure calculation. Meanwhile the dynamics of the system on the time-scale of femtoseconds can be accounted for using the Bohr-Oppenheimer approximation. Rather than relying only on the vibrational degrees of freedom at the ground state of the reactant/catalyst and the transition state of the reactant-catalyst complex to contribute to the free energy, this method can provide free energy contributions that account for anharmonicity of vibrational modes as well as free energy contributions from the chemical system as a whole, e.g., the free energy contributions from changes in fluctuations of the solvent structures of the reactant/catalyst individually as well in the reactant-catalyst complex. In some cases, molecular dynamics can be performed using machine learning force fields.

The ML model can be trained/fine-tuned on the dataset of the transition states and the features. During training/fine-tuning, the ML model can be coupled to a differentiable scoring function which is configured to provide gradients from the features of the transition states (e.g., the activation energy, transition state energy) to the ML model such that the ML model learns to generate more desirable catalysts—e.g., those that are more synthesizable, have low activation energies, etc.

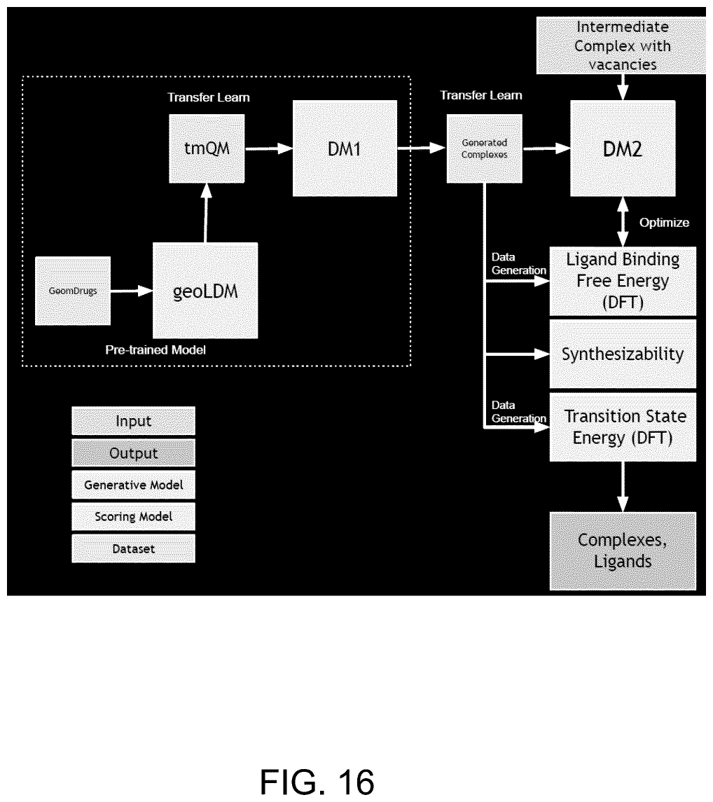

As described above, calculating the transition state and its energy can involve methods which have wide ranges of computational cost. To reduce the computational burden, the ML model can be trained on progressively refined datasets that increase in accuracy but also cost per data point. For example, the ML model can first be trained on activation potential energies calculated using TB, because TB is cheaper than DFT, as shown in FIG. 15. Then, the trained ML model can be used to generate a set of catalyst structures, which is subsequently used to generate a new dataset having activation potential energies calculated using DFT which is more expensive, as shown in FIG. 16. The ML model can be trained on the new dataset, then, the ML model can be used to generate an additional set of catalyst structures, which can be used to generate an additional dataset having activation free energies calculated using DFT and Car-Parrinello molecular dynamics with explicit solvent. The ML model can be trained the new dataset, and so forth. This progressive form of curating datasets and training the ML model can progressively narrow the distribution of molecules that the ML model is configured to generate in an informed manner. Subsequent generations of datasets and the ML model can allow refinement of the accuracy for smaller and more salient chemical spaces. This method can reduce the computational burden of performing the most-expensive and most accurate calculations a vast chemical space.

The present disclosure also provides methods and systems for predicting reaction paths using a general machine learned (ML) potential that can detect when it is unreliable and switch to a reliable, equivalent ab initio calculation instead. Predicting a reaction path can aid in determining the transition state structure in a reaction, as well as evaluating an activation energy along the reaction path. Generated transition state structures can be used to prepare a dataset for training a ML model for predicting catalyst structures. An ML potential may be the potential generated from an ML model that takes in at least an indication of molecular conformation and returns at least the energy of that conformation. The energy and force from the ab initio calculation may be directly used in place of the ML potential, and the data may be saved for later retraining of the ML potential. When combined with overall reaction path prediction algorithms, this technique may form a robust and rapid method for calculating reaction paths and transition states that continuously improves the underlying ML model. The calculated reaction paths and transition states can be used to train a ML model for predicting catalyst structures. In some cases, the technique for calculating reaction paths and transition states can be integrated into a ML model for predicting catalyst structures.

In some aspects, the present disclosure provides a computational chemistry platform that can predict a chemical reaction path accurately and efficiently by flexibly switching the energy and force solver between quantum chemistry or other chemical potential methods, such as DFT, CCSD(T), iFCI, QM/MM, DMET, ONIOM, and force field based potentials, and a machine learning (ML) model trained to the level of the quantum chemistry or chemical potential method depending on the reliability of the inference that the ML model provides. If the platform indicates that the ML inference for a geometry along the reaction path is reliable, the platform continues using the ML model for that geometry. But when the platform indicates that the ML inference is less reliable, the platform may switch to the quantum chemistry methods to solve the target geometry. In this way, the present disclosure increases both accuracy and efficiency.

In another example of increasing accuracy and efficiency, the results obtained from the quantum chemistry calculations may be stored in the platform's database as the training dataset to improve the ML model. In this way, the platform may reduce the number of times the quantum chemistry methods are used to solve the target geometry, and the platform may continuously improve the ML model to predict chemical reactions faster and more accurately.

FIG. 1 is a flowchart of an example of a method 100 for determining a reaction path. At an operation 110, the method may comprise providing an indication of a reactant and a product or a driving coordinate. At an operation 120, the method may comprise providing a set of coordinates on an energy surface. At an operation 130, the method may comprise evaluating an energy or a force using a trained model. At an operation 140, the method may comprise determining a reliability metric for the energy or the force at the coordinate determined with the trained model. At an operation 150, in response to the reliability metric the method may comprise, optionally, evaluating an energy or a force based on a quantum chemistry calculation.

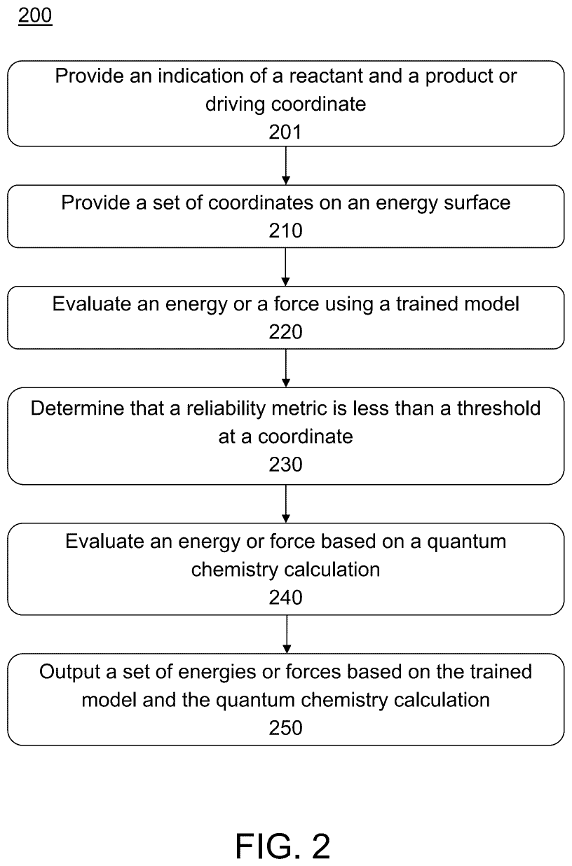

FIG. 2 is a flowchart of an example of a method 200 for determining a reaction path when the reliability is less than a threshold value. Method 200 may comprise an embodiment variation or example of method 100. At an operation 201, method 200 may comprise providing an indication of a reactant and at least one of a product or a driving coordinate. Operation 201 may comprise an embodiment, variation, or example of operation 110 of the method 100. At an operation 210, method 200 may comprise providing a set of coordinates. The set of coordinates may be on an energy surface connecting the reactant and at least one of the product or the driving coordinate. Operation 210 may comprise an embodiment, variation, or example of operation 120 of the method 100. At an operation 220, method 200 may comprise evaluating an energy or a force at a coordinate of the set of coordinates using a trained model. Operation 220 may comprise an embodiment, variation, or example of operation 130 of the method 100. At an operation 230, method 200 may comprise determining that a reliability metric at the coordinate is less than a threshold reliability value. Operation 230 may comprise an embodiment, variation, or example of operation 140 of the method 100 when the reliability metric is less than a threshold. At an operation 240, method 200 may comprise evaluating an energy or a force at the coordinate based at least in part on a quantum chemistry calculation corresponding to a training data set of the trained model. Operation 240 may comprise an embodiment, variation, or example of operation 150 of the method 100 when the energy or the force is calculated using the quantum chemistry calculation. At an operation 250, method 200 may comprise outputting a set of energies or forces at the set of coordinates on the energy surface based at least in part on the energy or force in 240 and the energy or the force in operation 220.

In an example of the method 200, the present disclosure provides a computer-implemented method for determining a reaction path. The method may comprise: (a) providing an indication of a reactant and at least one of a product or a driving coordinate; (b) providing a set of conformational coordinates, wherein the set of conformational coordinates is on a potential energy surface connecting the reactant and the at least one of the product or the driving coordinate; (c) using a trained model to evaluate an energy or a force at a conformational coordinate of the set of conformation coordinates; (d) determining that a reliability metric at the conformational coordinate is less than a threshold reliability value; (c) evaluating an ab initio energy or an ab initio force at the conformational coordinate; and (f) outputting a set of energies or forces at the set of conformational coordinates on the potential energy surface based at least in part on the ab initio energy or ab initio force and the energy or the force in (c).

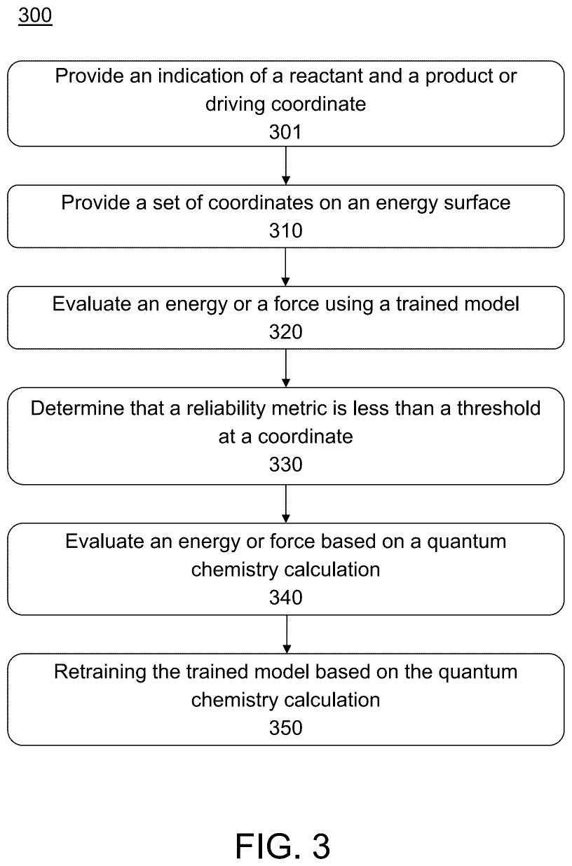

FIG. 3 is a flowchart of an example of a method 300 for determining a reaction path and using data from a quantum chemistry calculation to update a trained model. Method 300 may comprise an embodiment variation or example of method 100. At an operation 301, method 300 may comprise providing an indication of a reactant and at least one of a product or a driving coordinate. Operation 301 may comprise an embodiment, variation, or example of operation 110 of the method 100. At an operation 310, method 300 may comprise providing a set of coordinates. The set of coordinates may be on an energy surface connecting the reactant and at least one of the product or the driving coordinate. Operation 310 may comprise an embodiment, variation, or example of operation 320 of the method 100. At an operation 320, method 300 may comprise evaluating an energy or a force at a coordinate of the set of coordinates using a trained model. Operation 320 may comprise an embodiment, variation, or example of operation 130 of the method 100. At an operation 330, method 300 may comprise determining that a reliability metric at the coordinate is less than a threshold reliability value. Operation 330 may comprise an embodiment, variation, or example of operation 140 of the method 100 when the reliability metric is less than a threshold. At an operation 340, method 300 may comprise evaluating an energy or a force at the coordinate based at least in part on a quantum chemistry calculation corresponding to a training data set of the trained model. Operation 340 may comprise an embodiment, variation, or example of operation 150 of the method 100 when the energy or the force is calculated using the quantum chemistry calculation. At an operation 350, method 300 may comprise retraining the trained model based on the energy or the force in 340.

In an example of the method 300, the present application provides a computer-implemented method for determining a reaction path. The method may comprise: (a) providing an indication of a reactant and at least one of a product or a driving coordinate; (b) providing a set of conformational coordinates, wherein the set of conformational coordinates is on a potential energy surface connecting the reactant and the at least one of the product or the driving coordinate; (c) using a trained model to evaluate an energy or a force at a conformational coordinate of the set of conformational coordinates; (d) evaluating an ab initio energy or an ab initio force at the conformational coordinate; and (c) retraining the trained model based on the ab initio energy or the ab initio force.

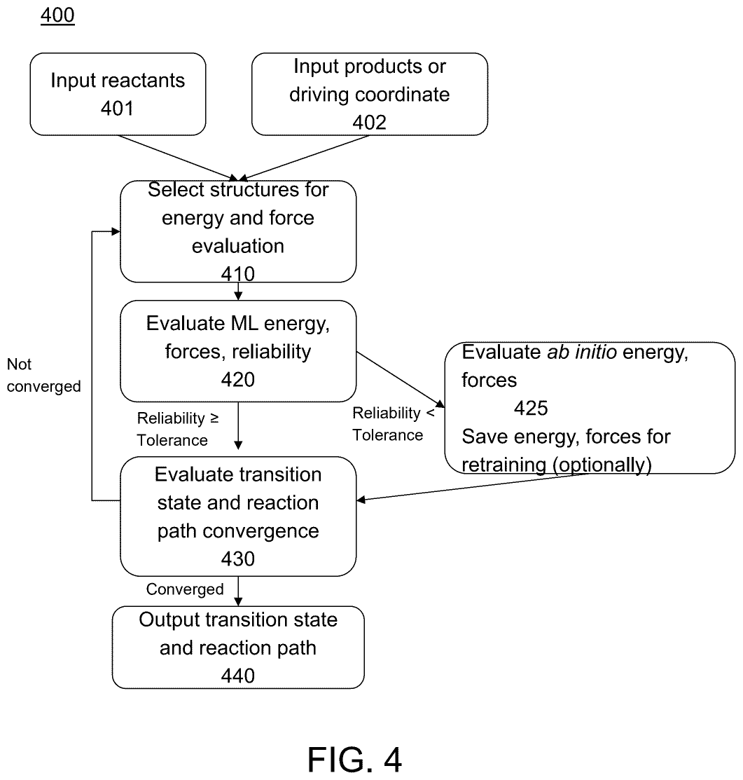

FIG. 4 is a flowchart an example of a method 400 for determining a reaction path showing branching pathways based on a reliability metric. Method 400 may comprise an embodiment variation or example of method 100.

At an operation 401, method 400 may comprise providing an indication of a reactant. At an operation 402, method 400 may comprise providing at least one of a product or a driving coordinate. The indication at operation 401, operation 402, or both may be inputs to the computer implemented methods described herein, for example, operation 110 of a method 100. An operation 401, operation 402, or both may comprise providing an indication of a reactant and at least one of a product or a driving coordinate. At an operation 410, method 400 may comprise selecting structures for energy evaluation, force evaluation, or both. An operation 410 may comprise providing a set of coordinates, wherein the set of coordinates is on an energy surface connecting the reactant and the at least one of the product or the driving coordinate. At an operation 420, method 400 may comprise evaluating an energy or a force at a coordinate of the set of coordinates using a trained model. Operation 420 may comprise an embodiment, variation, or example of operation 130 of the method 100. At an operation 420, method 400 may further comprise determining a reliability metric at the coordinate. Operation 420 may comprise an embodiment, variation, or example of operation 140 of the method 100. After an operation 420, method 400 may branch based on a reliability. In some cases, method 400 may comprise providing a threshold reliability value for an energy or a force at a coordinate of the set of coordinates. If a reliability metric is less than the threshold reliability value, the method 400 may proceed to operation 425. If a reliability metric is greater than the threshold reliability value, the method 400 may proceed to operation 435. At an operation 425, method 400 may comprise evaluating an energy or a force at the coordinate based at least in part on a quantum chemistry calculation corresponding to a training data set of the trained model. Operation 340 may comprise an embodiment, variation, or example of operation 150 of the method 100 when the energy or the force is calculated using the quantum chemistry calculation. selecting another coordinate on the energy surface, using a trained model to evaluate the energy or the force at another coordinate, and determining the reliability metric for the energy or the force at another coordinate. At an operation 430, method 400 may comprise, if the reliability metric is greater than the threshold reliability value, selecting another coordinate on the potential energy surface, using the trained model to evaluate the energy at another coordinate, and determining a reliability metric for the energy or the force at another coordinate. In some cases, method 400 may comprise repeating 410, 420, 425, and 430 until a stopping criterion is met. At an operation 440, method 400 may comprise outputting a set of energies or forces at the set of coordinates on the energy surface based at least in part on the energy or force in 430.

In an example of method 400, the present disclosure provides, a computer-implemented method for determining a reaction path. The method may comprise: (a) providing an indication of a reactant and at least one of a product or a driving coordinate; (b) providing a set of conformational coordinates, wherein the set of conformational coordinates is on a potential energy surface connecting the reactant and the at least one of the product or the driving coordinate; (c) providing a threshold reliability value for an energy or a force at a conformational coordinate of the set of conformational coordinates and, until a completion criterion is met: (i) if a reliability metric is less than the threshold reliability value: evaluating an ab initio energy or an ab initio force at the conformational coordinate, selecting another conformation coordinate on the potential energy surface, using a trained model to evaluate the energy or the force at the another conformational coordinate, and determining the reliability metric for the energy or the force at the another conformational coordinate; and (ii) if the reliability metric is greater than the threshold reliability value: selecting another conformational coordinate on the potential energy surface, using the trained model to evaluate the energy at the another conformational coordinate, and determining a reliability metric for the energy or the force at the another conformational coordinate; and (d) outputting a set of energies or forces at the set of conformational coordinates on the potential energy surface.

### Reaction Template

In some cases, a system or a method of the present disclosure can receive a reaction template. A reaction template can be an expression of a reaction in human readable or computer readable form. A reaction template can define one or more reactants, one or more products, one or more catalysts, and/or one or more reaction conditions. A reaction template can be in human-readable form, e.g., in a textual form. A reaction template can be in a computer-readable form, e.g., encoded into a matrix representation, graph representation, or both.

In some cases, a reaction template can comprise a structural template for the reaction. In some cases, a reaction template can comprise an elementary reaction. In some cases, a reaction template can comprise a plurality of elementary reactions. The plurality of elementary reactions can be processed in sequence or in parallel. In some cases, the reaction template comprises a transition metal complex comprising the catalyst. In some cases, the reaction template comprises a transition metal complex comprising the catalyst, an alkaline earth metal complex comprising the catalyst, a complex comprising a main group element comprising the catalyst, or a complex comprising a non-metallic element comprising the catalyst. In some cases, the reaction template comprises a transition state of the reaction. In some cases, the reaction template comprises a plurality of transition states of the reaction. In some cases, the reaction template comprises a plurality of reactants. In some cases, the reaction template comprises a plurality of products. In some cases, the reaction template comprises an environmental condition for the reaction. In some cases, the environmental condition comprises temperature, solvent, pressure, a presence of a gas, agitation, or any combination thereof.

In some cases, the reaction template comprises a string-based representation of the reaction. In some cases, the reaction template comprises a graph-based representation of the reaction. In some cases, the reaction template comprises a matrix-based representation of the reaction. In some cases, the matrix-based representation comprises an adjacency matrix. In some cases, the adjacency matrix comprises indicators for the formation or the destruction of bonds or both.

In some cases, the reaction template indicates a bond in the reactant that is created or broken in the reaction. In some cases, the reaction template indicates a bond in the product that is created or broken in the reaction. In some cases, the reaction template indicates an electron in the reactant or the product that is transferred in the reaction. In some cases, the reaction template comprises a reaction coordinate that represents a reaction path of the reaction. In some cases, the reaction coordinate comprises a collective variable.

In some cases, the catalyst comprises a heterogenous catalyst. In some cases, the heterogenous catalyst comprises a transition metal. In some cases, the heterogenous catalyst comprises a transition metal oxide. In some cases, the heterogenous catalyst comprises a catalyst support. In some cases, the catalyst comprises a homogenous catalyst. In some cases, the catalyst comprises a transition metal. In some cases, the catalyst comprises an organometallic. In some cases, the catalyst comprises a ligand. In some cases, the catalyst comprises a plurality of ligands. In some cases, the ligand comprises an organic ligand, an organometallic ligand, a halide, an ether, an alkoxide, an alcohol, a carboxylate, a heterocycle, an amine, an amide, an imine, a nitrile, a phosphine, a metallocene, an n-heterocyclic carbene, an alkyl, an alkene, an alkyne, or any combination thereof. In some cases, the chemical structure of the catalyst is attached to the reaction template.

### Reaction Path Sampling and Initialization

Reaction path sampling, sometimes called transition path sampling, may comprise a form of simulation in which trajectories of physical or chemical transitions of a system from one stable state to other are calculated. Examples of target systems for reaction path sampling include protein folding, chemical reactions, crystal nucleation, etc. Of interest in a reaction path sampling calculation is a transition state. In a simple example, a state A and a state B may be stable states of a system. State A and State B may be connected by a trajectory along a reaction path. The reaction may be characterized by a saddle point between the stable states. The saddle point may be the transition state. The transition state may be characterized by an activation energy barrier. In some cases, the reaction path may be characterized by an ensemble of transition paths. The transition state geometry and the activation energy barrier may be of interest in understanding chemical reactions (e.g., what chemical reactions happen) and rate constants (e.g., how fast they happen). These calculations may help generate understanding of important phenomena like docking a ligand at a protein, per- and polyfluoroalkyl substances (PFAS) reactions, etc.

However, these types of calculation may be difficult to perform. The transition state itself is a non-equilibrium state which may be difficult to model quantum chemical. Further, from a molecular dynamics perspective, the size of the ensemble of paths used to reach chemical accuracy may become quite large. As such, these may be promising systems for advanced quantum chemical methods.

Providing an indication of a reactant and a product or a driving coordinate: At an operation 110, the method may comprise providing an indication of a reactant and a product or a driving coordinate. Operation 201 may comprise an embodiment, variation, or example of operation 110 of the method 100. Operation 301 may comprise an embodiment, variation, or example of operation 110 of the method 100.

At an operation 401, method 400 may comprise providing an indication of a reactant. At an operation 402, method 400 may comprise providing at least one of a product or a driving coordinate. The indication at operation 401, operation 402, or both may be inputs to the computer implemented methods described herein, for example, operation 110 of a method 100. An operation 401, operation 402, or both may comprise providing an indication of a reactant and at least one of a product or a driving coordinate. The indication at operation 401, operation 402, or both may be provided by a user.

In some cases, the method may comprise providing an indication of a reactant. In some cases, the method may comprise providing an indication of a product or a driving coordinate. The indication of the reactant, the product, or both may comprise an indication of a chemical structure. In some cases, the structure is provided in a coordinate system. In some cases, the set of coordinates are a conformation coordinate. In some cases, the set of coordinates are cartesian coordinates. In some cases, the cartesian coordinates comprise a direction of movement. In some case, the indication of the reactant, the product, the driving coordinate or any combination of thereof comprise a simplified molecular-input line-entry system (SMILES) string. In some case, the indication of the reactant, the product, the driving coordinate or any combination of thereof comprise a 2D drawing. In some case, the indication of the reactant, the product, the driving coordinate or any combination of thereof comprise 3D model.

In some cases, the product may not be known at the start of a computation. In the case of an unknown product, a driving coordinate may be provided. A driving coordinate may comprise a bond bending coordinate, a bond breaking coordinate, a tortional coordinate, a stretching coordinate, a bending coordinate, a geometric distortion of the reactant of any kind, etc. In some cases, the driving coordinate is a direction of motion on a geometric coordinate system. In some cases, the driving coordinate is a direction of motion on energy coordinate system. In the case, where the product is unknown, the reaction path sampling calculation may be used to find the product.

The indication may be provided by a user. In some cases, the user provides the indication via an interface remote to a computing platform.

Providing a set of coordinates on an energy surface: At an operation 120, the method 100 may comprise providing a set of coordinates on an energy surface. Operation 210 may comprise an embodiment, variation, or example of operation 120 of the method 100. Operation 310 may comprise an embodiment, variation, or example of operation 320 of the method 100. At an operation 410, method 400 may comprise selecting structures for energy evaluation, force evaluation, or both. An operation 410 may comprise providing a set of coordinates, wherein the set of coordinates is on an energy surface connecting the reactant and the at least one of the product or the driving coordinate.

With the reactant and the product or the driving coordinate provided, the space within which the reaction path is to be determined may be provided. In some cases, the set of coordinates comprises a set of conformational coordinates. In some cases, the set of conformational coordinates is on an energy surface connecting the reactant and the at least one of the product or the driving coordinate. In some cases, energy surface is a potential energy surface. In some cases, the energy surface is a free energy surface.

In some cases, the method 100, 200, 300, or 400 may further comprise an operation of selecting a conformational coordinate within the set of conformational coordinates. In some cases, the method 100, 200, 300, or 400 may further comprise generating a first or initial coordinate. In some cases, the method 100, 200, 300, or 400 may further comprise using a trained model described herein below to evaluate a first energy or a first force at an initial coordinate. In some cases, the method 100, 200, 300, or 400 may further comprise determining a reliability metric for the first energy or the first force at the initial coordinate.

In some cases, providing a set of coordinates at 120 comprises a method selected from the group consisting of: ab initio molecular dynamics, nudged elastic band, growing string method, a variational reaction path optimization method, and intrinsic reaction coordinate. Any of the methods may be used to generate a set of coordinates and to move to a next coordinate within the set of coordinates. For example, there are various approaches to generate an intermediate or next molecular geometry and to follow the trajectory of molecules in the chemical reaction; such approaches include Ab Initio Molecular Dynamics (AIMD), NEB (Nudged Elastic Band), and GSM (Growing String Method), a variational reaction path optimization method, IRC (Intrinsic Reaction Coordinate) etc.

Reaction path prediction methods may seek to determine the minimum energy path (MEP) between a given point on the potential energy surface (or a free energy surface) and some goal, e.g., a product, a next conformational state, a next molecular coordinate, etc. In double ended methods, the goal is another point on the potential energy surface (or the free energy surface). In single ended methods, this goal is the first saddle point approximately in a given direction on the energy surface.

There are many methods that can be used to compute the MEP. Some rely on sampling the surface via metadynamics, (e.g., Born Oppenheimer molecular dynamics) and some explore the surface more directly with string-based methods (e.g., nudged elastic band (NEB) or growing string method (GSM)). Others form a reaction path from a transition state (e.g., intrinsic reaction coordinate). Each of these example methods may be integrated into the general outline shown in FIGS. 1-4.

In some cases, the method 100, 200, 300, or 400 further comprises if the reliability metric is greater than the threshold reliability value: selecting another conformational coordinate on the potential energy surface. The method may comprise using the trained model to evaluate the energy at another conformational coordinate and determining a reliability metric for the energy or the force at another conformational coordinate.

In some cases, the method 100, 200, 300, or 400 further comprises determining whether a completion condition is met. If the completion condition is not met, the method may comprise repeating operations 410, 420, 425, and 430 until the completion condition is met. The completion condition may comprise a reaching a threshold value, such as a maximum number of cycles, a threshold change in the energy, a threshold change in a reliability metric, etc.

In some cases, the method 100, 200, 300, or 400 further comprises outputting a transition state or a reaction path on the energy surface. In some cases, the reaction path is a minimum energy path. In some cases, the method 100, 200, 300, or 400 further comprises: outputting a set of energies or forces at the set of coordinates on the energy surface based at least in part on the energy or force calculated from the higher level of theory method (e.g., a quantum chemistry method).

In some cases, the method 100, 200, 300, or 400 further comprises outputting a set of energies or forces at the set of conformational coordinates on the potential energy surface. In some cases, the outputted set of energies or forces are output after a completion condition is met.

In some cases, the method 1100 further comprises if the reliability metric is greater than the threshold reliability value: generating a new catalyst structure. The new catalyst structure can be co-generated with a new transition state structure and/or a new activation energy.

In some cases, the method 1100 further comprises determining whether a completion condition is met. If the completion condition is not met, the method may comprise generating new catalyst structures until the completion condition is met. When the completion condition is met, the method may comprise outputting the chemical structure and/or the geometrical structure of the catalyst.

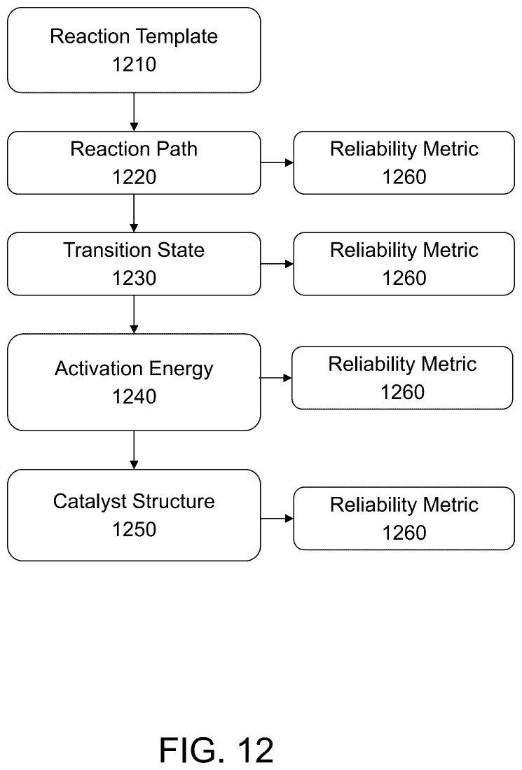

Methods and systems of the present disclosure may also be integrated with retraining or updating the trained model. For example, the present application provides methods and systems for determining a reaction path comprising retraining the trained model. Referring again to FIG. 3, there is a flowchart of an example of a method 300 for determining a reaction path and using data from a quantum chemistry calculation to update a trained model. At an operation 301, method 300 may comprise providing an indication of a reactant and at least one of a product or a driving coordinate. At an operation 310, method 300 may comprise providing a set of coordinates. The set of coordinates may be on an energy surface connecting the reactant and at least one of the product or the driving coordinate. At an operation 320, method 300 may comprise evaluating an energy or a force at a coordinate of the set of coordinates using a trained model. At an operation 330, method 300 may comprise determining that a reliability metric at the coordinate is less than a threshold reliability value. At an operation 340, method 300 may comprise evaluating an energy or a force at the coordinate based at least in part on a quantum chemistry calculation corresponding to a training data set of the trained model. At an operation 350, method 300 may comprise retraining the trained model based on the energy or the force in 340. Likewise, method 1100 can be retrained based on the outputs of the reliability metric that quantify the reliability of the reaction path, the transition state, the activation energy, and/or the catalyst structure. FIG. 12 shows one such example of the method.

In an example of the method 300, the present application provides a computer-implemented method for determining a reaction path. The method may comprise: (a) providing an indication of a reactant and at least one of a product or a driving coordinate; (b) providing a set of conformational coordinates, wherein the set of conformational coordinates is on a potential energy surface connecting the reactant and the at least one of the product or the driving coordinate; (c) using a trained model to evaluate an energy or a force at a conformational coordinate of the set of conformational coordinates; (d) evaluating an ab initio energy or an ab initio force at the conformational coordinate; and (c) retraining the trained model based on the ab initio energy or the ab initio force.

In some cases, the method 100, 200, 300, or 400 further comprises passing energies and forces based on the training data to machine learning model. In some cases, the energies and forces from a model corresponding to the training data may be passed back to the reaction path prediction algorithm. In some cases, the energies and forces from the quantum chemistry calculation may be passed back to the machine learning model. In some cases, the energies and forces from the quantum chemistry calculation may be passed back to the reaction path prediction algorithm. Once the reaction path prediction algorithm receives these quantities, it may continue. In some cases, it may continue with no other modifications. Retraining of the ML potential to incorporate the new data points generated above may occur separately to the reaction path prediction process. This retraining does not need to occur during the reaction path prediction process, although it may.

### Machine Learning

Because of the computational expense of certain computational methods, machine learning models have been proposed as alternatively for computationally expensive calculations. Machine learning (ML) methods may be used in various fields such as quantum chemistry and materials simulation. For example, ML methods may be used to deliver predictive models of interatomic potential energy surfaces, molecular forces, electron densities, density functionals, and molecular response properties such as polarizabilities and infrared spectra. Large data sets of molecular properties calculated from quantum chemistry or measured from experiment can both be used to construct predictive models to explore the vast chemical compound spaces, to find new sustainable catalyst materials, and to design new synthetic pathways. In some cases, machine learning can be used in constructing approximate quantum chemical methods, such as predicting MP2 and coupled cluster energies from Hartree-Fock orbitals. In some cases, neural networks may be used as a basis representation of the wavefunction. In general, ML models may learn from quantum chemistry datasets to describe molecular properties as scalar, vector, or tensor fields. In an example, quantum chemistry data of different electronic properties, such as energies or dipole moments, may be used to construct individual ML models for the respective properties. ML may allow for the efficient exploration of chemical space with respect to these properties.

Systems and methods of the present disclosure may implement various machine learning methods. Machine learning (ML) may comprise training (e.g., tuning parameters within) a flexible computer algorithm with a particular set of data. More specifically, ML may comprise supervised learning, semi-supervised learning, unsupervised learning, and reinforcement learning. In supervised learning, parameters within an ML model may be updated such that the output of the model and the labelled data yield a similar result. In unsupervised learning, a model may learn patterns within a particular dataset without labels. In semi-supervised learning, some labels may be present, and others are not. In reinforcement learning, a model may be used to determine what actions to take given a particular environment. A particular set of machine learning models, used In some cases, are neural networks, which may include the layers: fully connected, convolution, pooling, skip connections, etc. When many layers are connected in a neural network, this may be referred to as a deep learning model. Deep learning models have many parameters and require many datapoints to reduce the error in their predictions.

Examples of Machine Learning Methodologies—In some cases, at an operation 130, the method may comprise evaluating an energy or a force using a trained model. In some cases, the trained model comprises a machine learning algorithm. In some cases, ML may generally involve identifying and recognizing patterns in existing data in order to facilitate making predictions for subsequent data. ML may include a ML model (which may include, for example, a ML algorithm). Machine learning, whether analytical or statistical in nature, may provide deductive or abductive inference based on real or simulated data. The ML model may be a trained model.

ML techniques may comprise one or more supervised, semi-supervised, self-supervised, or unsupervised ML techniques. For example, an ML model may be a trained model that is trained through supervised learning (e.g., various parameters are determined as weights or scaling factors). ML may comprise one or more of regression analysis, regularization, classification, dimensionality reduction, ensemble learning, meta learning, association rule learning, cluster analysis, anomaly detection, deep learning, or ultra-deep learning. ML may comprise, but is not limited to: k-means, k-means clustering, k-nearest neighbors, learning vector quantization, linear regression, non-linear regression, least squares regression, partial least squares regression, logistic regression, stepwise regression, multivariate adaptive regression splines, ridge regression, principal component regression, least absolute shrinkage and selection operation (LASSO), least angle regression, canonical correlation analysis, factor analysis, independent component analysis, linear discriminant analysis, multidimensional scaling, non-negative matrix factorization, principal components analysis, principal coordinates analysis, projection pursuit, Sammon mapping, t-distributed stochastic neighbor embedding, AdaBoosting, boosting, gradient boosting, bootstrap aggregation, ensemble averaging, decision trees, conditional decision trees, boosted decision trees, gradient boosted decision trees, random forests, stacked generalization, Bayesian networks, Bayesian belief networks, naïve Bayes, Gaussian naïve Bayes, multinomial naïve Bayes, hidden Markov models, hierarchical hidden Markov models, support vector machines, encoders, decoders, auto-encoders, stacked auto-encoders, perceptrons, multi-layer perceptrons, artificial neural networks, feedforward neural networks, convolutional neural networks, recurrent neural networks, long short-term memory, deep belief networks, deep Boltzmann machines, deep convolutional neural networks, deep recurrent neural networks, or generative adversarial networks.

Training Data—The trained model may be trained on a data set of quantum chemical information. For example, a dataset may comprise the Transition 1X data set, see https://arxiv.org/abs/2207.12858, which is incorporated herein by reference for all purposes. In some cases, a base data set may be supplemented by data from a user base. For example, prior use quantum chemical calculations may be used to generate a proprietary data set or to supplement an existing one. A training data set may comprise a coordinate and an energy for a set of reactants and products. In some cases, a training data set may also comprise forces. A data set may be more accurate the larger the number of samples which are similar to the data point to be calculated. In some cases, a data set with more data with structures similar to the transition state may be more accurate.

Training—Training the ML model may include, in some cases, selecting one or more untrained data models to train using a training data set. The selected untrained data models may include any type of untrained ML models for supervised, semi-supervised, self-supervised, or unsupervised machine learning. The selected untrained data models may be specified based upon input (e.g., user input) specifying relevant parameters to use as predicted variables or other variables to use as potential explanatory variables. For example, the selected untrained data models may be specified to generate an output (e.g., a prediction) based upon the input. Conditions for training the ML model from the selected untrained data models may likewise be selected, such as limits on the ML model complexity or limits on the ML model refinement past a certain point. The ML model may be trained (e.g., via a computer system such as a server) using the training data set. In some cases, a first subset of the training data set may be selected to train the ML model. The selected untrained data models may then be trained on the first subset of training data set using appropriate ML techniques, based upon the type of ML model selected and any conditions specified for training the ML model. In some cases, due to the processing power requirements of training the ML model, the selected untrained data models may be trained using additional computing resources (e.g., cloud computing resources). Such computational resources may be employed in serial or in parallel. Such training may continue, in some cases, until at least one aspect of the ML model is validated and meets selection criteria to be used as a predictive model.

In some cases, one or more aspects of the ML model may be validated using a second subset of the training data set (e.g., distinct from the first subset of the training data set) to determine accuracy and robustness of the ML model. Such validation may include applying the ML model to the second subset of the training data set to make predictions derived from the second subset of the training data. The ML model may then be evaluated to determine whether performance is sufficient based upon the derived predictions. The sufficiency criteria applied to the ML model may vary depending upon the size of the training data set available for training, the performance of previous iterations of trained models, or user-specified performance requirements. If the ML model does not achieve sufficient performance, additional training may be performed. Additional training may include refinement of the ML model or retraining on a different first subset of the training dataset, after which the new ML model may again be validated and assessed. When the ML model has achieved sufficient performance, in some cases, the ML may be stored for present or future use. The ML model may be stored as sets of parameter values or weights for analysis of further input (e.g., further relevant parameters to use as further predicted variables, further explanatory variables, further user interaction data, etc.), which may also include analysis logic or indications of model validity in some instances. In some cases, a plurality of ML models may be stored for generating predictions under different sets of input data conditions. In some cases, the ML model may be stored in a database (e.g., associated with a server).

Neural Networks—In some cases, the machine learning algorithm comprises a neural network. One class of machine learning algorithms, artificial neural networks (ANNs), may comprise a portion of the trained model herein. For example, feedforward neural networks (such as convolutional neural networks or CNNs) and recurrent neural networks (RNNs) may be used. In some cases, multiple layers of neural networks may be employed, creating a deep neural network. Using a deep neural network may increase the predictive power of a neural network algorithm. In some cases, a machine learning algorithm using a neural network may further include Adam optimization (e.g., adaptive learning rate), stochastic gradient descent, regularization, etc. The number of layers, the number of nodes within the layer, a stride length in a convolutional neural network, a padding, a filter, etc. may be adjustable parameters in a neural network.

Ensemble Learning—In some cases, the machine learning algorithm comprises an ensemble learning method. Ensemble learning may be a machine learning technique that enhances accuracy and resilience in forecasting by merging predictions from multiple models.

Ensemble learning may create a large-scale metamodel by statistically combining the results from several smaller, simpler models. These smaller models may not need to have the same architecture, but they may predict the same or similar features to the larger model. In some cases, the output of the metamodel and each of the sub-models is the energy of the molecular system. The energy from the metamodel is the mean of the energies from the sub-models, which may be represented as

$${E}_{M e t a} = {\sum }_{i = 1}^{L} {E}_{i}$$

where L is the total number of sub-models in the ensemble.

In some cases, the ensemble learning method comprises an ANI architecture. A description of the ANI architecture is provided at: https://arxiv.org/ftp/arxiv/papers/1801/1801.09319.pdf, which is incorporated herein by reference for all purposes. If the reliability criterion is larger than a tolerance, then that structure may be used for retraining of the model.

The ANI model may take in the atomic numbers and coordinates in cartesian space, and it may predict an energy for the whole molecule. An example using ANI-1 is shown at, for example, https://arxiv.org/ftp/arxiv/papers/1610/1610.08935.pdf, which is incorporated herein by reference for all purposes.

The ANI model belongs to the family of general machine learned chemical potential methods. The ANI model is not specific to any particular atom or system type. However, in some cases, specific trained instances of it, such as ANI-1x and ANI-2x may have a constrained set of allowed atoms. The ML model, such as for example the ANI model, may directly predict the energy of the molecular system. Additional details of the ANI model may be found at, for example, https://arxiv.org/ftp/arxiv/papers/1610/1610.08935.pdf, which is incorporated herein by reference for all purposes. Since the input parameters for the ANI model comprise atomic coordinates, one may find the force on the molecule through automatic differentiation.

In some cases, the ensemble learning method comprises combining results from one or more sub-models to create a metamodel. In some cases, the ensemble learning method comprises a MACE or an espaloma architecture. In some cases, a sub-model within the meta-model comprises MACE or espaloma. MACE may comprise an equivariant message passing neural network, see https://arxiv.org/pdf/2206.07697.pdf, which is incorporated by reference herein in its entirety. Espaloma may comprise machine-learned molecular mechanics force field, see https://arxiv.org/abs/2307.07085, which is incorporated by reference herein in its entirety. In some cases, a sub-model within the metamodel comprises an ANI deep learning potential. In some cases, the one or more sub-models comprises one or more of polarizable atom interaction neural network (PaiNN), DimeNet++ deep learning potentials, or PauliNet. PaiNN (a deep learning potential) is described at, for example, https://arxiv.org/abs/2102.03150, which is incorporated herein by reference in its entirety. DimeNet++ is described at, for example, https://arxiv.org/abs/2011.14115, which is incorporated herein by reference in its entirety. PauliNet is described at, for example, https://arxiv.org/abs/1909.08423, which is incorporated herein by reference in its entirety. In some case, the one or more sub-models comprises SchNET, OCP, etc. SchNET is described at, for example, https://arxiv.org/abs/1712.06113, which is incorporated herein by reference in its entirety. Open catalyst project (OCP) also produces an AI model which may be used as a sub-model herein, see, for example, https://opencatalystproject.org/, which is incorporated herein by reference in its entirety.

### Automated Reliability

At an operation 140, the method may comprise determining a reliability metric for the energy or the force at the coordinate determined with the trained model. In some cases, the method may comprise determining a reliability metric. In some cases, a trained model and reaction path prediction may be combined to simultaneously provide highly reliable reaction path prediction and transition state determination. In some cases, the method may also continuously improve the ML model used to provide the potential along this path. For example, a reaction path prediction algorithm may be used to generate structures for investigation, which produces a set of molecular coordinates. Next, an ensemble general ML potential may be used to evaluate the energy, forces, and reliability at this set of molecular coordinates.

From there, two things may occur. If the ML potential is reliable enough, (e.g., the standard deviation is lower than an acceptance threshold), these energies and forces may be directly passed back to the reaction path prediction algorithm. If the ML potential is not reliable enough, a quantum chemistry calculation may be launched to calculate energies and forces ab initio. The type of quantum chemistry calculation launched may match that used to generate the original training dataset of the ML potential. For example, if the original training set was calculated using coupled cluster singles and doubles with the cc-pVTZ basis set, then that is the calculation that may be launched. The energies, forces, atomic numbers, and atomic coordinates from this calculation may be saved for further training of the ML potential.

In some cases, the method 100, 200, 300, or 400 further comprises, until a completion criterion is met: (i) if the reliability metric is less than the threshold reliability value: evaluating the energy or the force at the coordinate that was unreliable, selecting another coordinate on the energy surface, using the trained model to evaluate the energy or the force at the another coordinate, and determining a reliability metric for the energy or the force at the another coordinate; and (ii) if the reliability metric is greater than the threshold reliability value: selecting another coordinate on the energy surface, using the trained model to evaluate the energy at the another coordinate, and determining a reliability metric for the energy or the force at the another coordinate.

In some cases, at (i), the method further comprises saving the energy or force for retraining and retraining the trained model based on the energy or the force in (i). In some cases, selecting another coordinate on the energy surface comprises a method selected from the group consisting of: ab initio molecular dynamics, nudged elastic band, growing string method, a variational reaction path optimization method, and intrinsic reaction coordinates.

Referring back to FIG. 4, in some cases, the method may comprise an operation 425: if a reliability metric is less than the threshold reliability value: evaluating an ab initio energy or an ab initio force at the conformational coordinate. After operation 425, the method may comprise: selecting another conformation coordinate on the potential energy surface; using a trained model to evaluate the energy or the force at another conformational coordinate; and determining the reliability metric for the energy or the force at another conformational coordinate.

In some cases, the method may comprise an operation 430: if the reliability metric is greater than the threshold reliability value: selecting another conformational coordinate on the potential energy surface. After operation 425, the method may comprise using the trained model to evaluate the energy at another conformational coordinate and determining a reliability metric for the energy or the force at another conformational coordinate.

In some cases, the method may comprise an operation 440 determining whether a completion condition is met. If the completion condition is not met, the method may comprise repeating operations 410, 420, 425, and 430 until the completion condition is met.

In some cases, a trained model can predict a reaction path, a transition state, a catalyst structure, an activation energy of a reaction, or any combination thereof. Predicting the reaction path may be based on the catalyst structure. Predicting the transition state may be based on the reaction path. Predicting the activation energy may be based on the transition state. The reliability metric can be evaluated for each of these predictions.

Reliability Metric—In some cases, the method 100, 200, 300, or 400 further comprises determining a reliability metric. In some cases, a computational chemistry model can output its own reliability metric. For example, if the computational chemistry method outputs an error assessment, then the error estimate may be used as a reliability metric. A Bayesian model may be an example of a model that produces a measure of uncertainty. For example, gaussian process regression may produce a measure of uncertainty. In some cases, if a reaction path calculated is not smooth, then there may be a higher uncertainty of the value that is significantly off of a smooth curve. In some cases, the same ML model may be implemented a plurality of times and a standard deviation may be calculated.

In some cases, a reliability test includes standard deviation computation using the inference outcomes based on plurality of ML models. In some cases, the plurality of ML models is part of an ensemble learning model. In some cases, the reliability test includes the similarity search between the training dataset and the input query to identify its rareness. In some cases, the inference reliability test includes instance selection strategies for selecting critical instances to refine the ML models. Instance selection strategies include the uncertainty sampling approach, the query by committee approach, the expected model change approach, the expected error reduction approach, and the density weighted methods.

In some cases, determining a reliability metric comprises combining results from one or more sub-models to create a metamodel, calculating an energy for each of the one or more sub-models, and calculating a standard deviation of energy for the one or more sub-models. In some cases, the standard deviation comprises a part of the reliability metric. For example, one can estimate the reliability of a given evaluation by taking the standard deviation of the energies predicted by the sub-models of an ensemble learning method. In some cases, the standard deviation may be normalized based on the model architecture in order to produce a consistent estimate for the reliability of a model. For example, in the ensemble ANI architecture, the normalized standard deviation is given by:

$$ρ = \frac{σ}{\sqrt{N}}$$

where σ is the standard deviation in the usual sense, and N is the number of atoms in the molecule.

### Quantum Chemistry Calculation

At an operation 150, in response to the reliability metric the method may comprise, optionally, evaluating an energy or a force based on a quantum chemistry calculation. The quantum chemistry calculation may correspond to a training data set of said trained model. For example, the type of quantum chemistry calculation launched may match that used to generate the original training dataset of the ML potential. For example, if the original training set was calculated using coupled cluster singles and doubles with the cc-pVTZ basis set, then that is the calculation that may be launched. The energies, forces, atomic numbers, and atomic coordinates from this calculation may be saved for further training of the ML potential.

For example, if the ML potential is not reliable enough, a quantum chemistry calculation may be launched to calculate energies and forces ab initio. The type of quantum chemistry calculation launched may match that used to generate the original training dataset of the ML potential. For example, if the original training set was calculated using coupled cluster singles and doubles with the cc-pVTZ basis set, then that is the calculation that may be launched. The energies, forces, atomic numbers, and atomic coordinates from this calculation may be saved for further training of the ML potential.

In some cases, evaluating an energy or a force based on a quantum chemistry calculation comprises evaluating an ab initio energy or an ab initio force at the coordinate. In some cases, the ab initio energy or the ab initio force is calculated by a Hartree-Fock method, a coupled cluster method, full configuration interaction, incremental full configuration interaction, density functional theory, Moller-Plesset perturbation theory, mixed quantum mechanical and molecular mechanical methods, density matrix embedding theory, or ONIOM models.

In some cases, computing the energy or the force comprises at least one member of the group consisting of Hartree-Fock (HF) method, Density Functional Theory (DFT), Coupled-Cluster Single-, Double-, and perturbative Triple-excitations (CCSD(T)), Full Configuration Interaction (FCI), Heat-Bath Configuration Interaction (HBCI), Quantum Monte Carlo Full Configuration Interaction (QMCFCI), Density Matrix Embedding Theory (DMET), Fragment Molecular Orbital method (FMO), Incremental Full Configuration Interaction (IFCI), Hybrid quantum mechanics-molecular mechanics (QM/MM), and Ab initio molecular dynamics (AIMD) simulation, Variational Monte Carlo, and Diffusion Monte Carlo.

In some cases, the activation energy of a reaction can be quantified by taking the difference in the potential energy of the transition state and the summed potential energy of the reactant(s) and the catalyst. The potential energy can be calculated using a physics-based computational chemistry method. In some cases, the physics-based computational chemistry method comprises TB, MMQM, DFT, FEP, or another electronic structure calculation. In some cases, the neural network is trained using data generated using experimental data.

In some cases, the activation energy of a reaction can be quantified by taking the difference in the free energy of the transition state and the summed free energy of the reactant(s) and the catalyst. The free energy can be calculated using DFT, or another electronic structure calculation. The electronic structure calculation can provide the Hessian, which can be used to calculate the free energy contributions that come from vibrational modes based on a harmonic assumption of the vibrational degrees of freedom. The electronic structure calculation can be performed using implicit or explicit solvent. Explicit solvent may be more accurate if the catalyst is expected to have specific interactions with the solvent that influences that molecular structure of the catalyst in the transition state and/or before binding with a reactant. The free energy can be calculated using a physics-based computational chemistry method.

Another way to compute the free energy is to perform Car-Parrinello molecular dynamics, where electronic degrees of freedom for the entire or a subset of the system is accounted for using an electronic structure calculation, while the dynamics of the system on the time-scale of femtoseconds is accounted for using the Bohr-Oppenheimer approximation. Rather than relying only on the vibrational degrees of freedom at the ground state of the reactant/catalyst and the transition state of the reactant-catalyst complex to contribute to the free energy, this method can provide free energy contributions that account for anharmonicity of vibrational modes as well as free energy contributions from the chemical system as a whole, e.g., the free energy contributions from changes in fluctuations of the solvent structures of the reactant/catalyst individually as well in the reactant-catalyst complex.

In some cases, the method 100, 200, 300, or 400 further comprises saving the energy or the force from a quantum chemistry calculation for retraining the trained model.

In some cases, the method 100, 200, 300, or 400 further comprises, after calculating the force or the energy with a higher level of theory, selecting another conformation coordinate on the energy surface. At the next coordinate, the method may comprise using a trained model to evaluate the energy or the force at the new conformational coordinate. At the new coordinate, the method may comprise determining the reliability metric for the energy or the force at the new conformational coordinate.

### Scoring Model

In some cases, systems and methods of the present disclosure may comprise differentiable machine learning models. A machine learning model may differentiable may comprise input variables that are input in such a way that a derivative may be defined. In an example, PyTorch may facilitate indexing of variables and operation on the variables, which all for each derivative and how parameters are connected to be monitored. A method of the present disclosure may comprise ranking one or more candidate structures of catalyst chemistries using a differentiable machine learning model to predict a score.

In some cases, a score is based on a chemical property of a catalyst. In some cases, the score comprises an indication of a binding affinity, a volume, a dipole moment, an interaction energy between the catalyst and the reaction, the activation energy of the reaction, etc. In some cases, the indication is a feasibility of the catalyst. In some cases, the feasibility comprises a binding affinity, an equilibrium constant, synthesizability, an activation energy of the reaction, a binding energy of the reactant to the catalyst, a molecular property of the catalyst, a molecular property of a reactant, a molecular property of a product, a reaction rate of the reaction, selectivity, solvent accessibility of a reaction site in the catalyst, or any combination thereof. In some cases, the molecular property comprise stability or a redox potential.

A property of the catalyst may further include ground state energy, excited states energies, highest occupied molecular orbital (HOMO)-lowest unoccupied molecular orbital (LUMO) gap, ionization potential, electron affinity, singlet-triplet gap, atomic charge, dipole moment, charge density, spectroscopic properties, peak position at X nm wherein X is the peak position, and binding affinity with a target molecule, equilibrium geometry, transition state geometry, reactivity, hydrophobicity, synthesizability, conformational entropy, and residence time of a molecule interacting with another molecule. In some more embodiments, the property of a molecule may further include effective carrier mass, acoustic wave propagation and elastic constants, the band structure, density of states, and forces on each atom and the stress tensor. In some cases, the property of a molecule may further include intercalation voltages, voltage profile, and phase diagram. In some cases, the property of a molecule may further include radial distribution functions, diffusion constant, viscosity, and conductivity.

The differentiable machine learning model may comprise use of a machine learning model. The third differentiable model may be a scoring model. In some cases, the third differentiable model is configured to mimic the results of a computational chemistry calculation. In some cases, the third differentiable model is configured to approximate the results of a quantum chemistry computation (such as DFT, CCSD(T), and FCI), Monte Carlo simulation, or a molecular dynamic simulation such as a free energy perturbation simulation. In some cases, the third differentiable model may be configured to approximate experimental results.

A quantum chemistry calculation may comprise a calculation to predict the electronic structure and molecular properties using quantum mechanics. A molecular mechanical calculation may comprise molecular modeling calculations based on the classical mechanics. A computational chemistry calculation may comprise a computer simulation to assist in solving chemical problems. A computational chemistry calculation may comprise quantum chemistry calculations. A quantum chemistry method may comprise at least one member of the group consisting of Density Functional Theory (DFT), Coupled-Cluster Single-, Double-, and perturbative Triple-excitations (CCSD(T)), Full Configuration Interaction (FCI), Heat-Bath Configuration Interaction (HBCI), Quantum Monte Carlo Full Configuration Interaction (QMCFCI), Density Matrix Embedding Theory (DMET), Fragment Molecular Orbital method (FMO), Incremental Full Configuration Interaction (IFCI), ML-based Schrodinger equation solver such as Paulinet, Hybrid quantum mechanics-molecular mechanics (QM/MM), and ab initio molecular dynamics (AIMD) simulation. The computational chemistry calculation may further comprise molecular mechanical calculations.

The differentiable model may predict a chemical property of a catalyst, such as any chemical property disclosed herein. For example, the differentiable model may predict a binding affinity, a volume of the molecule, a dipole moment, or an interaction energy between the input structure and the plurality of candidate structures. In some cases, the task may comprise computing energy, computing electronic structure, optimizing molecular geometry, performing the transition state search, performing conformational search, performing molecular similarity search, performing classical molecular dynamics simulation, performing ab initio molecular dynamics simulation, performing protein structure prediction, performing protein binding site prediction, performing virtual screening, performing protein-ligand binding structure prediction, performing free energy perturbation, performing ligand optimization, performing catalyst optimization, performing reaction path prediction, performing synthesizability prediction, performing spectroscopic information prediction, performing reactivity prediction, performing toxicity prediction, performing the binding structure prediction between enzyme and substrate, performing the structure prediction of self-assembled nanomaterials, optimizing the composition of the material, optimizing the experimental condition, or any combination thereof.

In an example, the machine learning model may predict the property of the catalyst based on training data comprising a set of catalysts whose relevant property has already been determined experimentally or using a quantum chemical computation. For example, if the property is a binding affinity, the third machine learning model may be trained on a set of molecules with known binding affinities.

The at least one machine learning (ML) model may be of various types, such as any machine learning model (ML) described elsewhere herein. In some cases, the machine learning (ML) model is based on supervised learning. In some cases, the machine learning (ML) model is based on unsupervised learning. In some cases, the machine learning (ML) model is based on reinforcement learning. In some cases, the machine learning (ML) model is based on active learning. In some cases, the machine learning (ML) model is based on semi-supervised learning. In some cases, the machine learning (ML) model is based on continuous learning. In some cases, the machine learning (ML) model is based on transfer learning. In some cases, modern machine learning (ML) models include an Artificial Neural Network (ANN), a Convolutional Neural Network (CNN), a Graph Neural Network (GNN), a message passing neural network, a transformer network, an autoencoder (AE), a variational autoencoder (VAE), and a Generative Adversarial Network (GAN). These methods utilize automatic differentiation and gradient descent techniques. In some cases, classical machine learning (ML) modes include a kernel ridge regressor, a random forest regressor, a gradient boosting regressor, a linear regressor, a logistic regressor, a ridge regressor, a lasso regressor, a polynomial regressor, a Bayesian regressor, an elastic net regressor, a principal component regressor, a least squares regressor, a support vector regressor. Some implementations of such ML models may not utilize automatic differentiation and use optimization strategies other than gradient descent. For such aforementioned models, ensemble models may be constructed by combining the predictions of 2 or more individual models.

In some cases, a method of the present disclosure comprises generating a scoring function. The scoring function may be differentiable. The scoring function may be a function of any score disclosed herein, e.g., a root mean square distance, a binding affinity, a volume of the molecule, a dipole moment, internal coordinates of a molecule, or an interaction energy between the catalyst and the reactant. The scoring function may be a function of a molecular coordinate. The scoring function may be a function of a latent variable.

In some cases, a method of the present disclosure may comprise backpropagating the score to a machine learning model to generate a catalyst structure. The machine learning model can be used to generate additional catalyst structures.

In some cases, gradients of the scoring function can be backpropagated to a machine learning model. In some cases, the scoring function can be used to update the machine learning model using a forward-forward algorithm. For example, the backpropagating may comprise differentiating the score with respect to the coordinates in the latent space to find a minimum or an approximation thereof and using the minimized coordinates in the machine learning model. For example, backpropagating may comprise evaluating each derivative collectively or in sequence. Each derivative may be attached via chain rule and therefore gradients may be computed backwards up until the gradients of the latent variables. Once these gradients are known, an optimization algorithm may be implemented to update the latent variables. In an example, where the first machine learning model is to be updated, the minimized variables can go into the first machine learning model, and the output of that can go into second machine learning model, etc. In some cases, the derivative of the score can be calculated with respect to the output of one machine learning model, and the derivative score may be used to update another machine learning model (e.g., bypassing the first). While backpropagating is provided as an example of propagating information or gradients through a neural network, other propagation methods also may be suitable. For example, In some cases, forward-forward algorithm may be used instead.

### Computer Systems

Systems and methods of the present disclosure may implement various operations on a digital computer. In some cases, a digital computer comprises one or more hardware central processing units (CPUs) that carry out the digital computer's functions. In some cases, the digital computer further comprises an operating system configured to perform executable instructions. In some cases, the digital computer is connected to a computer network. In some cases, the digital computer is connected to the Internet such that it accesses the World Wide Web. In some cases, the digital computer is connected to a cloud computing infrastructure. In some cases, the digital computer is connected to an intranet. In some cases, the digital computer is connected to a data storage device.

Various types of digital computer may be used. In fact, suitable digital computers may include, by way of non-limiting examples, server computers, desktop computers, laptop computers, notebook computers, sub-notebook computers, netbook computers, netbook computers, set-top computers, media streaming devices, handheld computers, Internet appliances, mobile smartphones, tablet computers, personal digital assistants, video game consoles, and vehicles. Smartphones may be suitable for use with one or more examples of the method and the system described herein. Select televisions, video players, and digital music players, in some cases with computer network connectivity, may be suitable for use in some cases of the system and the method described herein. Suitable tablet computers may include those with booklet, slate, and convertible configurations.

In some cases, the digital computer comprises an operating system configured to perform executable instructions. The operating system may be, for example, software, comprising programs and data, which manages the device's hardware and provides services for execution of applications. Various types of operating system may be used. For example, suitable server operating systems include, by way of non-limiting examples, FreeBSD, OpenBSD, NetBSD®, Linux, Apple® Mac OS X Server®, Oracle® Solaris®, Windows Server®, and Novell® NetWare®. Suitable personal computer operating systems may include, by way of non-limiting examples, Microsoft® Windows®, Apple® Mac OS X®, UNIX®, and UNIX-like operating systems such as GNU/Linux®. In some cases, the operating system is provided by cloud computing. Suitable mobile smart phone operating systems may include, by way of non-limiting examples, Nokia® Symbian® OS, Apple® iOS®, Research In Motion® BlackBerry OS®, Google® Android®, Microsoft® Windows Phone® OS, Microsoft® Windows Mobile® OS, Linux®, and Palm® WebOS®. Suitable media streaming device operating systems may include, by way of non-limiting examples, Apple TV®, Roku®, Boxee®, Google TV®, Google Chromecast®, Amazon Fire®, and Samsung® HomeSync®. Suitable video game console operating systems may include, by way of non-limiting examples, Sony® PS3®, Sony® PS4®, Microsoft® Xbox 360®, Microsoft® Xbox One®, Nintendo® Wii®, Nintendo® Wii U®, and Ouya®.

In some cases, the digital computer comprises a storage and/or memory device. Various types of storage and/or memory may be used in the digital computer. In some cases, the storage and/or memory device comprises one or more physical apparatuses used to store data or programs on a temporary or permanent basis. In some cases, the device comprises a volatile memory and requires power to maintain stored information. In some cases, the device comprises non-volatile memory and retains stored information when the digital computer is not powered. In some cases, the non-volatile memory comprises a flash memory. In some cases, the non-volatile memory comprises a dynamic random-access memory (DRAM). In some cases, the non-volatile memory comprises a ferroelectric random-access memory (FRAM). In some cases, the non-volatile memory comprises a phase-change random access memory (PRAM). In some cases, the device comprises a storage device including, by way of non-limiting examples, CD-ROMs, DVDs, flash memory devices, magnetic disk drives, magnetic tapes drives, optical disk drives, and cloud computing-based storage. In some cases, the storage and/or memory device comprises a combination of devices, such as those disclosed herein.

In some cases, the digital computer comprises a display used for providing visual information to a user. Various types of display may be used. In some cases, the display comprises a cathode ray tube (CRT). In some cases, the display comprises a liquid crystal display (LCD). In some cases, the display comprises a thin film transistor liquid crystal display (TFT-LCD). In some cases, the display comprises an organic light-emitting diode (OLED) display. In some cases, an OLED display comprises a passive-matrix OLED (PMOLED) or active-matrix OLED (AMOLED) display. In some cases, the display comprises a plasma display. In some cases, the display comprises a video projector. In some cases, the display comprises a combination of devices, such as those disclosed herein.

In some cases, the digital computer comprises an input device to receive information from a user. Various types of input devices may be used. In some cases, the input device comprises a keyboard. In some cases, the input device comprises a pointing device including, by way of non-limiting examples, a mouse, trackball, trackpad, joystick, game controller, or stylus. In some cases, the input device comprises a touch screen or a multi-touch screen. In some cases, the input device comprises a microphone to capture voice or other sound input. In some cases, the input device comprises a video camera or other sensor to capture motion or visual input. In some cases, the input device comprises a Kinect™, Leap Motion™, or the like. In some cases, the input device comprises a combination of devices, such as those disclosed herein.

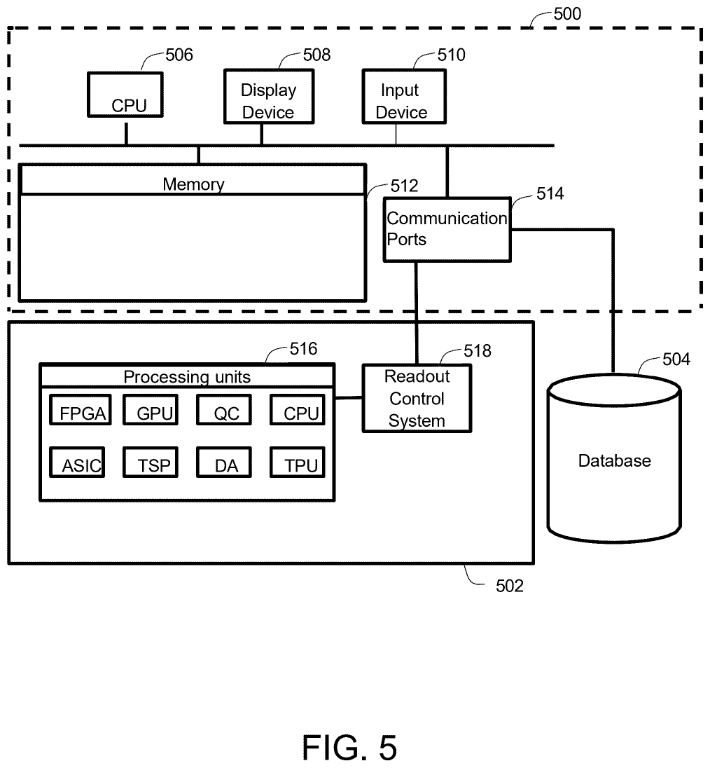

Now referring to FIG. 5, there is shown an example schematic diagram of a system for determining a reaction path. The system is configured to determine a reaction path utilizing one or more machine learning (ML) models, e.g., a neural network, an ensemble machine learning model, etc.

The system may comprise a digital computer 500. The digital computer may be a digital computer of various types, such as, for example, a digital computer as described elsewhere herein. The digital computer may comprise at least one processing device 506 and at least one memory 512. The at least one memory may comprise a computer program executable by the processing device 506 which may be configured to provide or receive an indication of a reactant and a product or a driving coordinate; provide or receive a set of coordinates on an energy surface; evaluate an energy or a force using a trained model; determine a reliability metric for the energy or the force at the coordinate determined with the trained model; and, in response to the reliability metric, optionally, evaluate an energy or a force based on a quantum chemistry calculation.

The system may comprise a computational platform 502 operatively connected to the digital computer 500. The computational platform 502 may comprise at least one processor 516. The at least one processor 516 may be of various types of processors such as, for example, the types of processors as described elsewhere herein. The at least one processor can include Noisy Intermediate-Scale Quantum (NISQ) technology, any quantum device, any high-performance computing device any quantum annealer, any optical computing device, an integrated photonic coherent Ising machine etc. For example, the at least one processor can comprise at least one field-programmable gate array (FPGA), application-specific integrated circuit (ASIC), central processing unit (CPU), graphics processing unit (GPU), tensor processing unit (TPU), tensor streaming processor (TSP), quantum computer, quantum annealer, integrated photonic coherent Ising machine, optical quantum computer, or the like, or any combination thereof. The computational platform 502 may be provided by a cloud computing system. In some cases, computational platform 502 comprises an array of distributed high performance computing units. The distributed high performance computing units may comprise processing units of various types as described herein.

Each component of the system (e.g., the hardware) may be used as part of the system to execute a whole method, or any portion thereof, alone or in combination with other components (e.g., other hardware). In some cases, the components may be used for obtaining a request comprising an indication of at least one property of a molecule and a task, performing inference on at least one machine learning (ML) model using the obtained indication, performing inference reliability test, if the reliability is satisfactory obtaining task result using the inference outcomes, if the reliability is not satisfactory, performing the task to obtain task result.

The computational platform 502 may be operatively connected to the digital computer 500. The computational platform may be communicatively coupled to the digital computer. The computational platform may comprise a read-out control system 518. The read-out control system may be configured to read information (e.g., computational results, parameters, etc.) from the at least one processor 516. For example, the read-out control system can be configured to convert data from an FPGA to data usable by a digital computer.

The system may comprise a database 504. The database 504 may be operatively connected to the digital computer 500. The database 504 may be a database of various types. The database 504 may refer to a central repository configured to save the specification of the task and task results. In some cases, the database can be, for example, MongoDB. The database 504 may be used to store indications of properties of molecules, corresponding tasks and results thereof. The database 504 may be used to store the task results. The database 504 may be further used to store the output from chemistry discovery toolbox. The database 504 may be further used to store the dataset for training the ML models. The dataset for training ML models may be a subset or complete set of task results. The dataset for training ML models may further be a subset or complete set of the output from chemistry discovery toolbox. The processing device 506 may be further configured to store in the database 504 indications of properties of molecules, corresponding tasks and the results thereof and to read from the database 504 indications of properties of molecules.

The computational platform 502 and the database 504 may be connected to the digital computer 500 over a network. The computational platform, the database, and/or the digital computer can have network communication devices. The network communication devices can enable the computational platform, the database, and/or the digital computer to communicate with each other and with any number of user devices, over a network. The network can be a wired or wireless network. For example, the network can be a fiber optic network, Ethernet® network, a satellite network, a cellular network, a Wi-Fi® network, a Bluetooth® network, or the like. In one or more implementations, the computational platform, the database, and/or digital computer can be several distributed computational platforms, databases, and/or the digital computers that are accessible through the Internet. Such computational platforms, databases, and/or digital computers may be considered cloud computing devices. In some cases, the one or more processors of the at least one processor may be located in the cloud.

The at least one processor 516 may comprise one or more virtual machines. The one or more virtual machines may be one or more emulations of one or more computer systems. The virtual machines may be process virtual machines (e.g., virtual machines configured to implement a process in a platform-independent environment). The virtual machines may be systems virtual machines (e.g., virtual machines configured to execute an operating system and related programs). The virtual machine may be configured to emulate a different architecture from the at least one processor. For example, the virtual machine may be configured to emulate a quantum computing architecture on a silicon computer chip. Examples of virtual machines may include, but are not limited to, VMware®, VirtualBox®, Parallels®, QEMU®, Citrix® Hypervisor, Microsoft® Hyper-V®, or the like.

The system of FIG. 5 may provide or receive an indication of a reactant and at least one of a product or a driving coordinate; provide or receive a set of conformational coordinates, wherein the set of conformational coordinates is on a potential energy surface connecting the reactant and the at least one of the product or the driving coordinate; use a trained model to evaluate an energy or a force at a conformational coordinate of the set of conformation coordinates; determine a reliability metric at the conformational coordinate; and, optionally, evaluate an ab initio energy or an ab initio force at the conformational coordinate.

In some cases, at an input device 516, digital computer 500 may receive a set of conformational coordinates, an indication of a reactant, at least one of a product or a driving coordinate, or any combination thereof. In some cases, at a processor 506, the system may, based on an indication from a user, provide a set of conformational coordinates, an indication of a reactant, at least one of a product or a driving coordinate, or any combination thereof. In some cases, digital computer 500 is a device of a user providing a user access to an application programming interface.

In some cases, the system is configured to use a trained model to evaluate an energy or a force at a conformational coordinate of the set of conformation coordinates. In some cases, the system is configured direct a processing unit 516 to do any of the following: use a trained model to evaluate an energy or a force at a conformational coordinate of the set of conformation coordinates; determine a reliability metric at the conformational coordinate; evaluate an ab initio energy or an ab initio force at the conformational coordinate; or any combination thereof. The system may implement the trained model over a communication port. In some cases, the system is configured direct a CPU 506 to do any of the following: use a trained model to evaluate an energy or a force at a conformational coordinate of the set of conformation coordinates; determine a reliability metric at the conformational coordinate; evaluate an ab initio energy or an ab initio force at the conformational coordinate; or any combination thereof. In some cases, processing unit 516 comprises an array of distributed high performance computing units. The distributed high performance computing units may comprise processing units of various types as described herein.

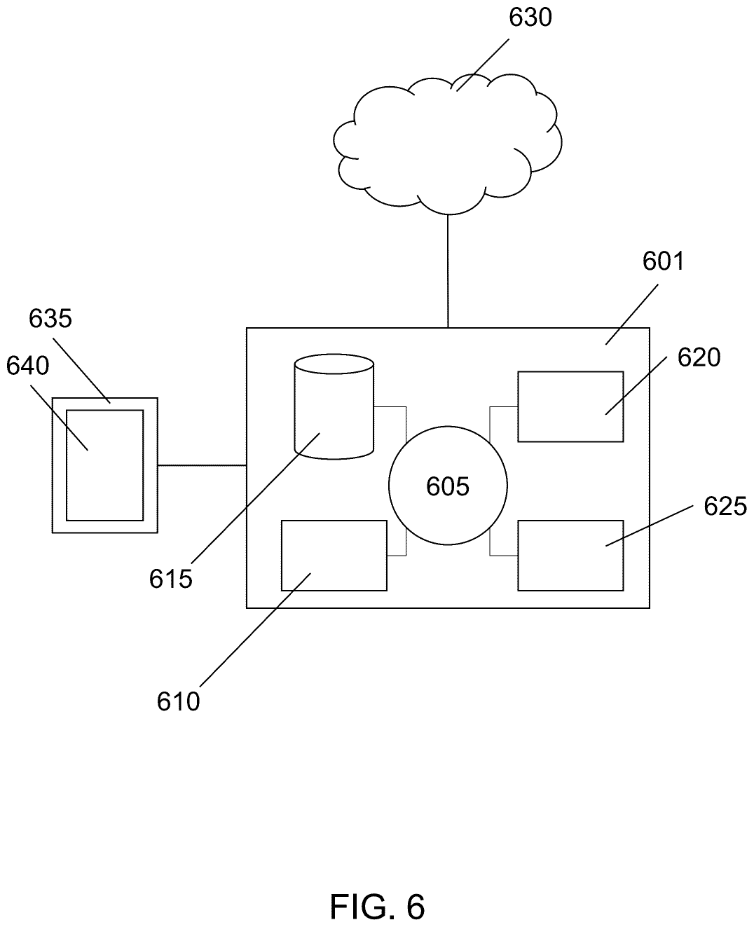

The present disclosure provides computer systems that are programmed to implement methods of the disclosure. FIG. 6 shows a computer system 601 that is programmed or otherwise configured to perform operations of the methods for determining a reaction path disclosed herein. Computer system 601 may comprise an embodiment variation or example of a digital computer 500 of FIG. 5. For example, computer system 601 may be programmed or otherwise configured to (a) provide or receive an indication of a reactant and at least one of a product or a driving coordinate; (b) provide or receive a set of conformational coordinates, wherein the set of conformational coordinates is on a potential energy surface connecting the reactant and the at least one of the product or the driving coordinate; (c) use a trained model to evaluate an energy or a force at a conformational coordinate of the set of conformation coordinates; (d) determine that a reliability metric at the conformational coordinate is less than a threshold reliability value; (c) evaluate an ab initio energy or an ab initio force at the conformational coordinate; and (f) output a set of energies or forces at the set of conformational coordinates on the potential energy surface based at least in part on the ab initio energy or ab initio force and the energy or the force.

The computer system 601 can be an electronic device of a user or a computer system that is remotely located with respect to the electronic device. The electronic device can be a mobile electronic device.

The computer system 601 includes a central processing unit (CPU, e.g., CPU 506, also “processor” and “computer processor” herein) 605, which can be a single core or multi core processor, or a plurality of processors for parallel processing. The computer system 601 also includes memory or memory location 610 (e.g., random-access memory, read-only memory, flash memory, e.g., memory 512), electronic storage unit 615 (e.g., hard disk), communication interface 620 (e.g., network adapter, e.g., communication port 514) for communicating with one or more other systems, and peripheral devices 625, such as cache, other memory, data storage and/or electronic display adapters. The memory 610, storage unit 615, interface 620 and peripheral devices 625 are in communication with the CPU 605 through a communication bus (solid lines), such as a motherboard. The storage unit 615 can be a data storage unit (or data repository) for storing data. The computer system 601 can be operatively coupled to a computer network (“network”) 630 with the aid of the communication interface 620. The network 630 can be the Internet, an internet and/or extranet, or an intranet and/or extranet that is in communication with the Internet. The network 630 in some cases is a telecommunication and/or data network. The network 630 can include one or more computer servers, which can enable distributed computing, such as cloud computing. The network 630, in some cases with the aid of the computer system 601, can implement a peer-to-peer network, which may enable devices coupled to the computer system 601 to behave as a client or a server.

The CPU 605 can execute a sequence of machine-readable instructions, which can be embodied in a program or software. The instructions may be stored in a memory location, such as the memory 610. The instructions can be directed to the CPU 605, which can subsequently program or otherwise configure the CPU 605 to implement methods of the present disclosure. Examples of operations performed by the CPU 605 can include fetch, decode, execute, and writeback.

The CPU 605 can be part of a circuit, such as an integrated circuit. One or more other components of the system 601 can be included in the circuit. In some cases, the circuit is an application specific integrated circuit (ASIC).

The storage unit 615 can store files, such as drivers, libraries and saved programs. The storage unit 615 can store user data, e.g., user preferences and user programs. The computer system 601 in some cases can include one or more additional data storage units that are external to the computer system 601, such as located on a remote server that is in communication with the computer system 601 through an intranet or the Internet.

The computer system 601 can communicate with one or more remote computer systems through the network 630. For instance, the computer system 601 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 601 via the network 630.

Methods as described herein can be implemented by way of machine (e.g., computer processor) executable code stored on an electronic storage location of the computer system 601, such as, for example, on the memory 610 or electronic storage unit 615. The machine executable or machine-readable code can be provided in the form of software. During use, the code can be executed by the processor 605. In some cases, the code can be retrieved from the storage unit 615 and stored on the memory 610 for ready access by the processor 605. In some situations, the electronic storage unit 615 can be precluded, and machine-executable instructions are stored on memory 610.

The code can be pre-compiled and configured for use with a machine having a processer adapted to execute the code or can be compiled during runtime. The code can be supplied in a programming language that can be selected to enable the code to execute in a pre-compiled or as-compiled fashion.

Aspects of the systems and methods provided herein, such as the computer system 601, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 601 can include or be in communication with an electronic display 635 (e.g., display device 508) that comprises a user interface (UI) 640 (e.g., input device 510) for providing, for example, an output of coordinates, structures, energies, geometries, etc. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 605. The algorithm can, for example, execute one or more operations of the methods for determining a reaction path disclosed herein.

### Quantum Computer System

In some cases, the systems and methods disclosed herein may be performed with the aid of a quantum computing system. In some cases, a computer-implemented method of the present disclosure may be performed at least partially by a quantum computer. In some cases, a computing system of the present disclosure may comprise a hybrid computing unit. In some cases, a hybrid computing unit may comprise a classical computer and quantum computer. The quantum computer may be configured to perform one or more quantum algorithms for solving a computational problem (e.g., at least a portion of a reaction path calculation). A quantum processor may comprise processing unit QC of element 516 of FIG. 5.

The one or more quantum algorithms may be executed using a quantum computer, a quantum-ready computing service, or a quantum-enabled computing service. For instance, the one or more quantum algorithms may be executed using the systems or methods described in U.S. Patent Publication No. 2018/0107526, entitled “METHODS AND SYSTEMS FOR QUANTUM READY AND QUANTUM ENABLED COMPUTATIONS”, which is entirely incorporated herein by reference. The classical computer may comprise at least one classical processor and computer memory and may be configured to perform one or more classical algorithms for solving a computational problem (e.g., at least a portion of a reaction path calculation).

The digital computer may comprise at least one computer processor and computer memory, wherein the digital computer may include a computer program with instructions executable by the at least one computer processor to render an application. The application may facilitate use of the quantum computer and/or the classical computer by a user.

Some implementations may use quantum computers along with classical computers operating on bits, such as personal desktops, laptops, supercomputers, distributed computing, clusters, cloud-based computing resources, smartphones, or tablets.

The system may comprise an interface for a user. In some cases, the interface may comprise an application programming interface (API). The interface may provide a programmatic model that abstracts away (e.g., by hiding from the user) the internal details (e.g., architecture and operations) of the quantum computer. In some cases, the interface may minimize a need to update the application programs in response to changing quantum hardware. In some cases, the interface may remain unchanged when the quantum computer has a change in internal structure.

The present disclosure provides systems and methods that may include non-classical (e.g., quantum) computing or use of non-classical (e.g., quantum) computing. Quantum computers may be able to solve certain classes of computational tasks more efficiently than classical computers. However, quantum computation resources may be rare and expensive, and may involve a certain level of expertise to be used efficiently or effectively (e.g., cost-efficiently or cost-effectively). A number of parameters may be tuned in order for a quantum computer to deliver its potential computational power.

Quantum computers (or other types of non-classical computers) may be able to work alongside classical computers as co-processors. A hybrid architecture (e.g., computing system) comprising a classical computer and a quantum computer can be very efficient for addressing complex computational tasks, such as quantum chemistry simulations. Systems and methods disclosed herein may be able to efficiently and accurately decompose or break down a quantum chemistry problem and delegate appropriate components of the quantum chemistry simulations to the quantum computer or the classical computer.

Although the present disclosure has referred to quantum computers, methods and systems of the present disclosure may be employed for use with other types of computers, which may be non-classical computers. Such non-classical computers may comprise quantum computers, hybrid quantum computers, quantum-type computers, or other computers that are not classical computers. Examples of non-classical computers may include, but are not limited to, Hitachi Ising solvers, coherent Ising machines based on optical parameters, and other solvers which utilize different physical phenomena to obtain more efficiency in solving particular classes of problems.

In some cases, a quantum computer may comprise one or more adiabatic quantum computers, quantum gate arrays, one-way quantum computers, topological quantum computers, quantum Turing machines, superconductor-based quantum computers, trapped ion quantum computers, trapped atom quantum computers, optical lattices, quantum dot computers, spin-based quantum computers, spatial-based quantum computers, Loss-DiVincenzo quantum computers, nuclear magnetic resonance (NMR) based quantum computers, solution-state NMR quantum computers, solid-state NMR quantum computers, solid-state NMR Kane quantum computers, electrons-on-helium quantum computers, cavity-quantum-electrodynamics based quantum computers, molecular magnet quantum computers, fullerene-based quantum computers, linear optical quantum computers, diamond-based quantum computers, nitrogen vacancy (NV) diamond-based quantum computers, Bose-Einstein condensate-based quantum computers, transistor-based quantum computers, and rare-earth-metal-ion-doped inorganic crystal based quantum computers. A quantum computer may comprise one or more of: quantum annealers, Ising solvers, optical parametric oscillators (OPO), and gate models of quantum computing.

In some cases, a non-classical computer of the present disclosure may comprise a noisy intermediate-scale quantum device. “Noisy” may imply that incomplete control over the qubits is present and the “Intermediate-Scale” may refer to the number of qubits which may range from 50 to a few hundreds. Several physical systems made from superconducting qubits, artificial atoms, ion traps are proposed so far as feasible candidates to build NISQ quantum device and ultimately universal quantum computers.

In some cases, a classical simulator of the quantum circuit can be used which can run on a classical computer like a MacBook Pro laptop, a Windows laptop, or a Linux laptop. In some cases, the classical simulator can run on a cloud computing platform having access to multiple computing nodes in a parallel or distributed manner. In some cases, all or a portion of a quantum mechanical energy and/or electronic structure calculation may be performed using the classical simulator.

The methods described herein may be performed on an analogue quantum simulator. An analogue quantum simulator may be a quantum mechanical system consisting of a plurality of manufactured qubits. An analogue quantum simulator may be designed to simulate quantum systems by using physically different but mathematically equivalent or approximately equivalent systems. In an analogue quantum simulator, each qubit may be realized in an ion of strings of trapped atomic ions in linear radiofrequency traps. To each qubit may be coupled a source of bias called a local field bias. The local field biases on the qubits may be programmable and controllable. In some cases, a qubit control system comprising a digital processing unit is connected to the system of qubits and is capable of programming and tuning the local field biases on the qubits.

### EXAMPLES

### Example 1: Diels Alder GSM Experiment

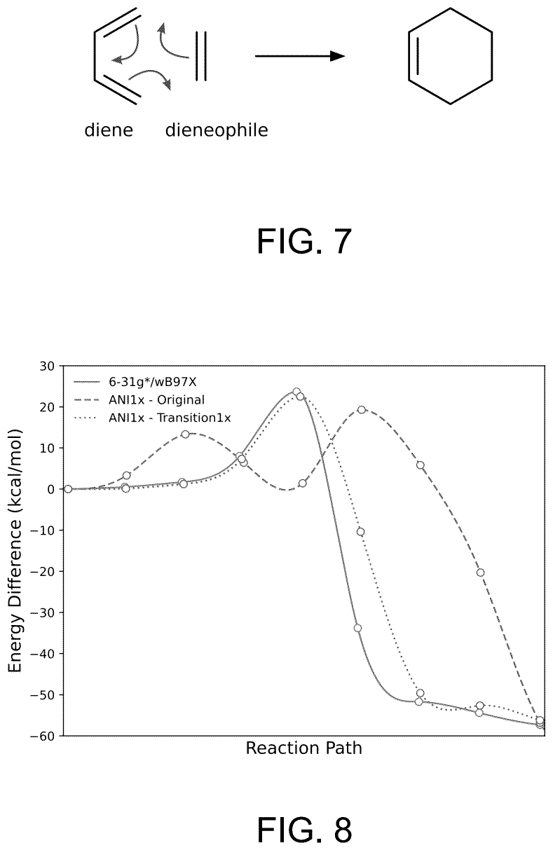

FIG. 7 is a diagram of a chemical reaction between s-cis-butadiene and ethene to form cyclohexene. The Growing String Method (GSM) was used to predict the transition state and reaction path coming from the s-cis-butadiene+ethene→cyclohexene reaction, shown in FIG. 7. This reaction path was predicted using several different models to evaluate the efficacy of the ML model with different training data. It was found that this experiment was a proof-of-concept that ML models can effectively model transition states and reaction paths when retrained on relevant data. It has been shown that when an ensemble ML model has high variability, running a quantum chemistry calculation and retraining the ML model on that data, the ML model will have a high chance of success at reaction path prediction.

Methods: The following energy and force evaluators were used: Density functional theory (DFT) at the 6-31G*/ωB97X level of theory. The ANI-1x machine learning (ML) model trained on the original ANI-1x dataset, referred to as “ANI/ANI1x.” The ANI-1x ML model trained on the Transition-1x dataset, referred to as “ANI/Transition1x.” For each evaluator, the reactant and product structures were optimized to local minima prior to the GSM calculation. GSM calculations were then performed using the corresponding evaluator to calculate the energy and forces of each GSM node during the string growing and optimization process.

Results: Reaction path prediction algorithms can be evaluated both on the quality of the transition state they predict and the overall quality of the reaction path that is calculated. In this case, the ANI/ANI1x evaluator both performed worse quantitatively than the ANI/Transition1x evaluator and failed to qualitatively predict the correct transition state.

To compare these models quantitatively, the absolute energies and reaction barriers of each ML evaluator are compared to the DFT evaluator. (Sec Table 1 for values) The deviation of the ANI/ANI1x evaluator from the DFT results is approximately 0.0117 Hartree and 4.4 kcal/mol for the absolute energy and reaction barrier, respectively. The deviation of the ANI/Transition1x evaluator from the DFT results is approximately 0.0040 Hartree and 1.2 kcal/mol, respectively. Not only does the ANI/Transition1x evaluator outperform the ANI/ANI1x evaluator, but it also predicts a reaction barrier to nearly within chemical accuracy (1 kcal/mol) of the DFT result.

FIG. 8 is a plot of computational data showing: reaction path energy profiles for DFT (solid), ANI/ANI1x (dashed), and ANI/Transition1x (dotted); GSM node energies (open circles); and intermediate values estimated with a cubic spline interpolation (regression lines). Qualitatively, it can be seen that the ANI/ANI1x evaluator predicts a different reaction mechanism than both DFT and ANI/Transition1x. DFT and ANI/Transition1x predict the correct transition state where the ethene approaches the butadiene from outside the butadiene bonding plane, ANI/ANI1x predicts a transition state that involves torsion of the C2-C3 bond and direct attachment of the ethene across the bonding plane of the butadiene. This can be seen in the reaction path where the double-barrier nature of the ANI/ANI1x reaction path comes from butadiene torsion first and bond formation second.

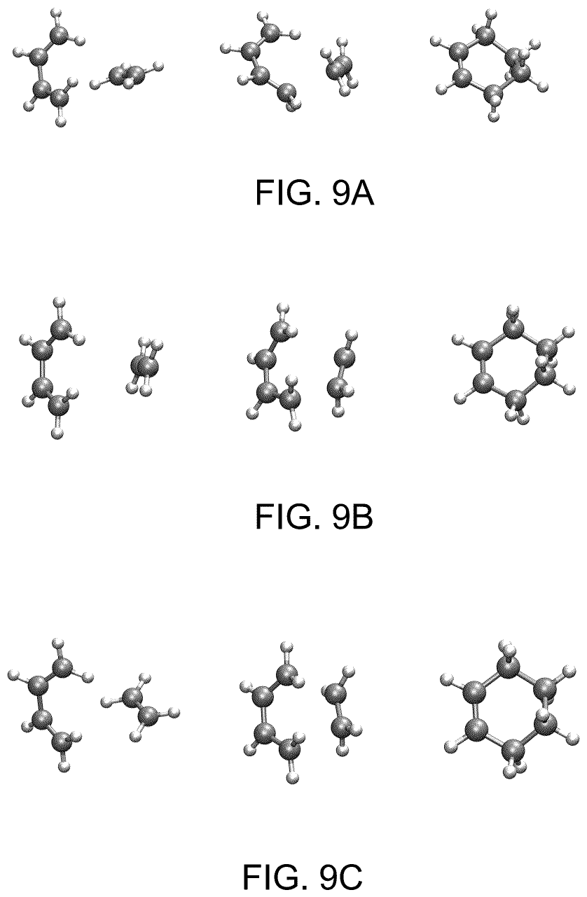

FIG. 9A is computational data showing molecular structures for the reactants (left), transition state (center), and products (right) predicted by GSM using the ANI/ANI1x model. FIG. 9B is computational data showing molecular structures for the reactants (left), transition state (center), and products (right) predicted by GSM using the ANI/Transition1x model. FIG. 9C is computational data showing molecular structures for the reactants (left), transition state (center), and products (right) predicted by GSM using the DFT model. As shown from the snapshots of the transition state geometries (center) in FIG. 9A-9C, the ANI/ANI1x evaluator predicts a different reaction mechanism than both DFT and ANI/Transition1x. DFT and ANI/Transition1x predict the correct transition state where the ethene approaches the butadiene from outside the butadiene bonding plane, ANI/ANI1x predicts a transition state that involves torsion of the C2-C3 bond and direct attachment of the ethene across the bonding plane of the butadiene

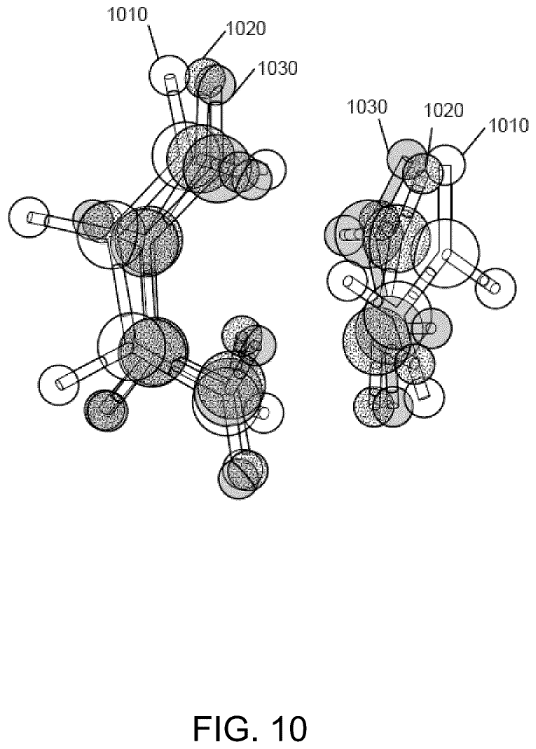

FIG. 10 shows overlaid transition state structures predicted by GSM using DFT, (filled, 1030) ANI/ANI1x, (open, 1010) and ANI/Transition1x. (textured, 1020), where all structures have been translated to have the same overall center of mass. As shown, FIG. 10 also indicates differences in transition state structures.

TABLE 1
Absolute energy of the transition state and reaction barrier
predicted by GSM using each energy and force evaluator.

| | Absolute energy | Reaction barrier |
|---|---|---|
| Evaluator | (Hartree) | (kcal/mol) |
| DFT | −234.45489899 | 23.7 |
| ANI/ANI1x | −234.46654967 | 19.3 |
| ANI/Transition1x | −234.45889929 | 22.5 |

### Example 2: Generating Novel Catalyst Chemistries

This is a prophetic example.

### Generating a Transition Metal Complex Structure by Optimizing the Properties of a Transition Metal Complex in an Inactive State

FIG. 14 illustrates a schematic for making and using a model for generating transition metal complexes. A diffusion model having roto-translational equivariant constraints with a point-structured latent space, invariant scalars, equivariant tensors can be constructed. The diffusion model can comprise an encoder that encodes molecular features into equivariant latent variables. The latent diffusion transitions can add noise to the latent variables in a series of steps such that the latent variables converge to Gaussians. During inference, an initial latent variable can be sampled from a normal distribution. The latent variable can be denoised in a series of equivariant denoising steps. The resulting denoised latent variable can be decoded back to a molecular point cloud with a decoder. The model can be pretrained with a dataset having various molecules, conformations, and energy annotations, e.g., GEOM or GEOMDRUGS which can have tens of millions of samples.

The model can be trained/fine-tuned on a dataset of transition metal complexes. As datasets regarding transition metal complexes are smaller, pretraining on a larger dataset such as GEOM or GEOMDRUGS allows the model to generalize better to unseen molecular structures. This generalization can perform well because transition metal complexes may include ligands which may have similar geometries and energetics as similar ligands/molecules found in a GEOM or GEOMDRUGS dataset.

The dataset can comprises various features such as the geometries, atomic charges (e.g., natural atomic charges), bond orders (e.g., Wiberg bond orders), energies, and/or forces. Other features can also be obtained from electronic structure calculations using available software like ORCA or GAUSSIAN. The tmQM dataset, for example, has 108k transition metal complexes including transition metals across the 3d, 4d, and 5d series combined with more than 30k different ligands, and also including organometallic, bioinorganic, and Werner complexes.

Prior to training/fine-tuning, the transition metal complex dataset can be augmented with annotations/labels that are useful for steering the generation of catalysts towards desirable properties. Using the chemical structures and the molecular geometries in the dataset, further electronic structure calculations or molecular dynamics simulations can be performed to obtain band gap energies, polarizability, synthesizability, ligand binding free energy, etc.

During training/fine-tuning, the diffusion model can be coupled to a differentiable scoring function which is configured to provide gradients from these annotations/labels to the diffusion model such that the diffusion model learns to generate more desirable catalysts—e.g., those that are more synthesizable, have favorable ligand binding free energies (e.g., favorable but not too strong so that ligands may be released after a reaction), etc. The differentiable scoring function can be trained independently and prior to the training of the diffusion model with the annotations/labels. The differentiable scoring function can also be trained with the diffusion model at the same time. Alternatively, the differentiable scoring function can be used not during training the diffusion model, but only during inference (as described in below).

Once trained, the diffusion model can be used to generate catalyst structures by providing a structure of a transition metal complex with one or more vacancies (e.g., open functional groups where specific ligand structures can be generated). The structure can be encoded into a latent space, and the diffusion model can generate denoising vectors that iteratively update the latent variable. The denoising vectors can be generated with feedback from the differentiable scoring function such that the denoising vectors are aimed towards generating transition metal complexes that have more desirable characteristics, e.g., better synthesizability, better ligand binding free energies, etc. Desirable characteristics can also include macroscopic properties of the catalyst in reactors, such as flow distribution, heat and mass transfer, etc. The denoising vectors can be deterministic, such that the gradients of the scoring functions can flow all the way back to the first step of the denoising process. The denoised latent variable is decoded to generate a molecular structure of the transition metal binding complex.

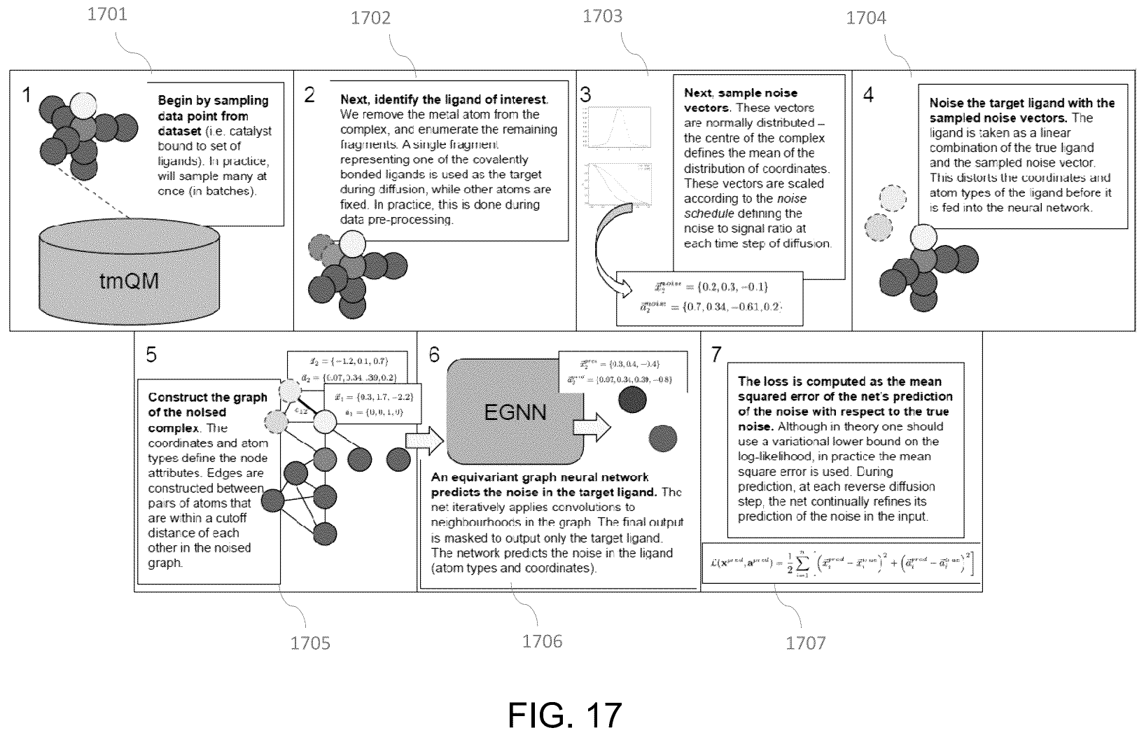

FIG. 17 illustrates a schematic for training the model. The ML is trained using a dataset 1701 having structures of the catalyst-ligand complexes. The dataset can be pre-processed 1702 by removing metal atoms from the complexes, and enumerating the remaining fragments from the complex. One of the ligands among the fragments is selected as the target during diffusion, and other atoms are fixed.

Noise vectors that are normally distributed at the center of the complex are sampled 1703. The normal distribution represents the prior that the atoms of the complex are distributed around the center. The vectors can be scaled according to the noise schedule that defines the noise to signal ratio at each time step of the diffusion. The target ligand is noised with the sampled noise vectors 1704. The ligand is then the linear combination of the ligand and the series of noise vectors.

A graph is constructed with the noised complex 1705. The coordinates and atom types define the node attributes, and edges are constructed between pairs of atoms that are within a cutoff distance of one another in the graph.

An equivariant neural network is trained to predict the noise of the target ligand 1706. The neural network is configured to apply convolutions to neighborhoods in the graph. The final output can be masked to output only the target ligand. The neural network predicts the noise in the ligand (e.g., atom types and coordinates), and the loss function 1707 is computed as the mean squared error of the neural network's prediction of the noise with respect to the true noise. While a variational lower bound of the log-likelihood can define the difference between the prediction and the true noise, in practice, a mean-squared error can be used.

### Example 3: Generating Novel Catalyst Chemistries

This is a prophetic example.

### Generating a Transition Metal Complex Structure by Optimizing the Properties of a Transition Metal Complex in Both Active and Inactive States

The trained diffusion model from Example 2 can be used to generate a large dataset of catalyst structures. While the diffusion model can be trained towards generating catalyst structures that meet the objectives defined by the differentiable scoring functions, the distribution of structures can be further refined by allowing the model to learn on information about the transition state structures or transition state energies of those structures. Without being bound to a particular theory, the transition theory of chemical reactions (e.g., as expressed by the Arrhenius equation or the Eyring equation) indicates that there is an exponential relationship between the activation energy of a reaction and the reaction rate. Thus, the transition state structure and the activation energy of the reaction (which can be quantified as the difference in energy between the transition state versus the reactants), can provide salient information regarding viable catalyst structure generation. Thus, this example describes generating a training dataset by calculating the activation energy of a large number of chemical reactions involving transition metal catalysts using computational chemistry and other methods disclosed herein. The training dataset can be then used to train the diffusion model to provide a new distribution of catalyst structures that are more likely to be successful ex silico. FIG. 15 illustrates a schematic for making and using a model for generating transition metal complexes.

### Transition State Sampling

Using a method of the present disclosure (e.g., as outlined in Example 1), transition states of numerous catalysts are sampled. Other methods can be used, e.g., nudged-elastic band, adaptive bias sampling, etc. The structure of the catalysts can come from the dataset of transition metal binding complexes generated by the diffusion model of Example 2.

### Activation Energy Calculation—Potential Energy

The activation energy of the reaction can be quantified by taking the difference in the potential energy of the transition state and the summed potential energy of the reactant(s) and the catalyst. The potential energy can be calculated using Tight Binding (TB), density function theory (DFT), or another electronic structure calculation.

### Activation Energy Calculation—Free Energy

The activation energy of the reaction can be quantified by taking the difference in the free energy of the transition state and the summed free energy of the reactant(s) and the catalyst. The free energy can be calculated using TB, DFT, or another electronic structure calculation. The electronic structure calculation can provide the Hessian, which can be used to calculate the free energy contributions that come from vibrational modes based on a harmonic assumption of the vibrational degrees of freedom. The electronic structure calculation can be performed using implicit or explicit solvent. Explicit solvent may be more accurate if the catalyst is expected to have specific interactions with the solvent that influences that molecular structure of the catalyst in the transition state and/or before binding with a reactant.

Another way to compute the free energy is to perform Car-Parrinello molecular dynamics, where electronic degrees of freedom for the entire or a subset of the system is accounted for using an electronic structure calculation, while the dynamics of the system on the time-scale of femtoseconds is accounted for using the Bohr-Oppenheimer approximation. Rather than relying only on the vibrational degrees of freedom at the ground state of the reactant/catalyst and the transition state of the reactant-catalyst complex to contribute to the free energy, this method can provide free energy contributions that account for anharmonicity of vibrational modes as well as free energy contributions from the chemical system as a whole, e.g., the free energy contributions from changes in fluctuations of the solvent structures of the reactant/catalyst individually as well in the reactant-catalyst complex.

### Training

The diffusion model is then trained/fine-tuned on the dataset of transition states and activation energies. During training/fine-tuning, the diffusion model can be coupled to a differentiable scoring function which is configured to provide gradients from features of the transition state (e.g., the activation energy, transition state energy) to the diffusion model such that the diffusion model learns to generate more desirable catalysts—e.g., those that are more synthesizable, have low activation energies, etc.

### Progressive Training

As described above, calculating the transition state and its energy can involves methods which have wide ranges of computational cost. To reduce the computational burden, the diffusion model can be trained on progressively refined datasets that increase in accuracy but also cost per data point. For example, the diffusion model can first be trained on activation potential energies calculated using TB, because TB is cheaper than DFT, as shown in FIG. 15. Then, the trained diffusion model can be used to generate a set of catalyst structures, which is subsequently used to generate a new dataset having activation potential energies calculated using DFT which is more expensive, as shown in FIG. 16. The diffusion model can be trained on the new dataset, then, the diffusion model can be used to generate an additional set of catalyst structures, which can be used to generate an additional dataset having activation free energies calculated using DFT and Car-Parrinello molecular dynamics with explicit solvent. The diffusion model can be trained on the new dataset, and so forth. This progressive form of curating datasets and training the diffusion model can progressively narrow the distribution of molecules that the diffusion model is configured to generate in an informed manner. Subsequent generations of datasets and the diffusion model allows refining the accuracy on smaller and more salient chemical spaces. This method can reduce the computational burden of performing the most-expensive and most accurate calculations in a vast chemical space.

### Neural Network Architecture

Various neural network architectures are considered, but by way of example, another architecture is provided here. An equivariant diffusion model is configured to receive atomic numbers, coordinates, bond information, or any combination thereof, of the complex with vacancy. The reactant, the catalyst (with open ligands), and the product are modeled as a collection of nodes, connected with bonds in the molecules before the reaction, as well as bonds that would form and break through the reaction. The neural network is configured to receive coordinates with random noise added, representing random coordinates of the nodes, and output a denoising vector that represents a reverse diffusion process that moves the nodes closer to the transition state structure when diffusion time reaches t=0. The neural network is also configured to output a probability of a particular atom type (e.g., C, H, or O) for each node. A mask is applied to outputs of the neural network model such that only mutable parts can be diffused (in either coordinates, atom type, or both).

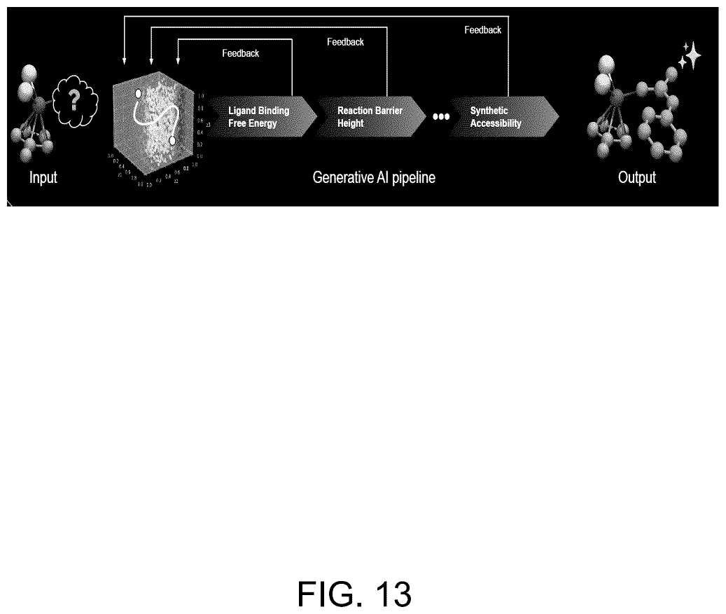

The neural network comprises a latent variable generator. The neural network is configured to generate a latent vector that represents the structure of the catalyst and its ligands. Based on the latent vector, the neural network generates a graph of the catalyst that represents its atoms and bonds. The latent variable generator can be linked to a differentiable scoring function such that it generates catalysts that are most feasible. FIG. 13 shows a schematic of a method for steering the latent variable based on various differentiable scoring functions. The differentiable scoring functions can provide gradients for exploring the latent space to generate catalysts that have lower activation free energies, better stability, better synthesizability, etc.

### Latent Space Optimization

The neural network can comprise an input comprising a feature vector that describes positions and atom types of the reactant, the catalyst, or their bound complex. The feature vector can be a latent space vector generated by compressing the positions and the atom types (with or without any other features) into lower dimensional space. The compression can be performed using an autoencoder.

The latent vectors are linked to the differentiable scoring function via the computational graph. Thus, the gradients can be used to perform optimization (e.g., gradient descent) on the latent vector at any diffusion layer to provide catalyst structures with better scored features (e.g., lower activation energy, better synthesizability, etc.).

### Expected Improvements

This method is expected to provide better catalyst chemical structures faster than some other methods. The molecules produced are better in quality, so the time it takes to achieve quality chemistries is faster than other methods which do not utilize the advantages of the methods disclosed herein. The method can be used to reduce the computational cost and the time for generating high-quality candidates.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

What is claimed is:

1. A method of generating a catalyst for a reaction, comprising:
(a) obtaining a reaction template of the reaction, wherein the reaction template comprises a reactant; and
(b) processing the reaction template, using a neural network, to generate a chemical structure of the catalyst based on a differentiable scoring function, wherein the catalyst is configured to catalyze the reaction.

2. The method of claim 1, wherein the neural network is configured to predict an activation energy of the reaction, and wherein the activation energy is used to guide the generation of the chemical structure.

3. The method of claim 1, wherein the neural network is configured to predict an activation energy of the reaction, and wherein the activation energy is used to guide the training of the neural network.

4. The method of claim 1, wherein the reaction template comprises a structural template for the reaction.

5. The method of claim 1, wherein the reaction template comprises a transition metal complex comprising the catalyst, an alkaline earth metal complex comprising the catalyst, a complex comprising a main group element comprising the catalyst, or a complex comprising a non-metallic element comprising the catalyst.

6. The method of claim 1, wherein the reaction template comprises a binding structure between the reactant and the catalyst.

7. The method of claim 1, wherein the reaction template comprises a transition state of the reaction.

8. The method of claim 1, wherein the reaction template comprises a plurality of reactants.

9. The method of claim 1, wherein the reaction template comprises a product.

10. The method of claim 1, wherein the reaction template comprises a plurality of products.

11. The method of claim 1, wherein the reaction template comprises an environmental condition for the reaction.

12. The method of claim 11, wherein the environmental condition comprises temperature, solvent, additives, pressure, a presence of a gas, agitation, or any combination thereof.

13. The method of claim 1, wherein the reaction template comprises a string-based representation of the reaction.

14. The method of claim 1, wherein the reaction template comprises a graph-based representation of the reaction.

15. The method of claim 1, wherein the reaction template comprises a matrix-based representation of the reaction.

16. The method of claim 15, wherein the matrix-based representation comprises an adjacency matrix, wherein the adjacency matrix comprises indicators for the formation or the destruction of bonds.

17. The method of claim 1, wherein the reaction template indicates a bond in the reactant that is created or broken in the reaction.

18. The method of claim 1, wherein the reaction template indicates a bond in the product that is created or broken in the reaction.

19. A system comprising:
one or more computers and one or more storage devices on which are stored instructions that are operable, when executed by the one or more computers, to cause the one or more computers to perform operations for generating a catalyst for a reaction comprising:
(a) obtaining a reaction template of the reaction, wherein the reaction template comprises a reactant; and
(b) processing the reaction template, using a neural network, to generate a chemical structure of the catalyst based on a differentiable scoring function, wherein the catalyst is configured to catalyze the reaction.

20. One or more non-transitory computer storage media encoded with computer program instructions that when executed by one or more computers cause the one or more computers to perform operations for generating a catalyst for a reaction comprising:
(a) obtaining a reaction template of the reaction, wherein the reaction template comprises a reactant; and
(b) processing the reaction template, using a neural network, to generate a chemical structure of the catalyst based on a differentiable scoring function, wherein the catalyst is configured to catalyze the reaction.
